(19) United States
(12) Patent Application Publication
(10) Pub. No.: US 2026/0293650 A1
(43) Pub. Date: Sep. 24, 2026

(54) CONTACT WINDOW, MEMORY UNIT, AND MEMORY DEVICE AND FABRICATION METHOD THEREOF

(71) Applicants: Semiconductor Manufacturing Beijing Corporation, Beijing (CN); Semiconductor Manufacturing International (Shanghai) Corporation, Shanghai (CN)

(72) Inventor: Zhenchao SUI, Beijing (CN)

(21) Appl. No.: 19/572,172

(22) Filed: Mar. 19, 2026

(30) Foreign Application Priority Data
Mar. 20, 2025 (CN) 202510338869.5

(51) Int. Cl. H10W 20/41; G11C 5/06; H10B 63/00; H10B 63/10; H10W 20/00; H10W 20/44; H10W 20/48

(52) U.S. Cl. CPC H10W 20/435; G11C 5/063; H10B 63/10; H10B 63/20; H10B 63/34; H10B 63/84; H10W 20/033; H10W 20/056; H10W 20/4407; H10W 20/4421; H10W 20/4441; H10W 20/48

(57) ABSTRACT

A contact window, a memory unit, a memory device, and a fabrication method of the memory device are provided in the present disclosure. The contact window includes a conductive blocking layer, where the conductive barrier-layer encloses a hollow shell, an end of the hollow shell is a sealed structure configured with a bottom surface, the bottom surface of the sealed structure is electrically connected to a first device to-be-connected, another end of the hollow shell is an open structure not configured a bottom surface, and an end surface of the open structure is electrically connected to a second device to-be-connected; and further includes a filling metal. The filling metal fills a portion of the hollow shell enclosed by the conductive blocking layer.

### CROSS-REFERENCE TO RELATED APPLICATION

This application claims the priority of Chinese Patent Application No. 202510338869.5, filed on March 20, 2025, the content of which is incorporated herein by reference in its entirety.

### TECHNICAL FIELD

The present disclosure generally relates to the field of semiconductor fabrication and, more particularly, relates to a contact window, a memory unit, and a memory device and a fabrication method thereof.

### BACKGROUND

In recent years, phase-change memory devices have received extensive research due to features including low latency, balanced read/write times, long lifespan, low power consumption, desirable radiation resistance and like, and advantages of no physical limitation and easily implementing high-density memory applications.

In the phase-change memory devices, memory elements and switching devices are electrically connected via contact windows. Phase-change memory devices require relatively high current density to induce phase change in phase-change materials. However, due to relatively large contact areas between the contact windows and the memory elements and between the contact windows and the switching devices, relatively high current density is needed to induce the phase change of the phase-change materials, which can easily lead to excessive power consumption in the phase-change memory devices.

A common method is to reduce the contact area to increase current density and reduce energy consumption. However, current method of reducing the contact area may result in increased process complexity, higher processing costs and the like.

### SUMMARY

One aspect of the present disclosure provides a contact window. The contact window includes a conductive blocking layer, where the conductive barrier-layer encloses a hollow shell, an end of the hollow shell is a sealed structure configured with a bottom surface, the bottom surface of the sealed structure is electrically connected to a first device to-be-connected, another end of the hollow shell is an open structure not configured a bottom surface, and an end surface of the open structure is electrically connected to a second device to-be-connected; and further includes a filling metal. The filling metal fills a portion of the hollow shell enclosed by the conductive blocking layer.

Optionally, the filling metal fills a portion of the hollow shell enclosed by the conductive barrier-layer and adjacent to the first device to-be-connected; and/or the contact window further includes a first insulating material, filled between the filling metal and the second device to-be-connected.

Optionally, a surface of the first insulating material facing toward the second device to-be-connected is in a contact with the second device to-be-connected; and/or along a direction of a line connecting the filling metal and the second device to-be-connected, a thickness of the first insulating material is less than 1/2 of a distance between the filling metal and the second device to-be-connected; and/or the first insulating material is made of at least one of silicon nitride and silicon oxide.

Optionally, a thickness of the conductive barrier-layer is uniform; and/or a thickness of the conductive barrier-layer is in a range of 1 nm to 20 nm; and/or the conductive barrier-layer is made of at least one of titanium nitride, tantalum nitride, titanium, tantalum, and ruthenium.

Optionally, a ratio of a thickness of the filling metal to a depth of the hollow shell is less than 2/3; and/or the filling metal material is made of a material including tungsten, copper, and aluminum.

Another aspect of the present disclosure provides a memory unit. The memory unit includes a switching device; a first contact window. The first contact window includes a conductive blocking layer, where the conductive barrier-layer encloses a hollow shell, an end of the hollow shell is a sealed structure configured with a bottom surface, the bottom surface of the sealed structure is electrically connected to a first device to-be-connected, another end of the hollow shell is an open structure not configured a bottom surface, and an end surface of the open structure is electrically connected to a second device to-be-connected; and a filling metal, where the filling metal fills a portion of the hollow shell enclosed by the conductive blocking layer, and one end of the first contact window is electrically connected to one end of the switching device. The memory unit further includes a memory element, where the memory element is on a side of the first contact window away from the switching device and electrically connected to another end of the first contact window.

Optionally, the memory element is a phase-change memory element; and the memory element includes a phase-change layer electrically connected to the first contact window, and an upper-layer electrode on a surface of the phase-change layer away from the first contact window; and/or the switching device is a diode switching device; and the switching device includes a first doped layer electrically connected to the first contact window, and a second doped layer on a side of the first doped layer away from the first contact window, where a doped type of the second doped layer is different from a doped type of the first doped layer; and/or the switching device is a transistor switching device; and the switching device includes a gate structure; and a first doped layer and a second doped layer, where along a plane perpendicular to a line connecting the switching device and the memory element, the first doped layer and the second doped layer are on two sides of the gate structure, and the first doped layer is electrically connected to the first contact window.

Optionally, the switching device further includes a connection layer; and the connection layer is between the first doped layer and the first contact window.

Another aspect of the present disclosure provides a memory device. The memory device includes a memory array, where the memory array includes memory units of the present disclosure; the memory units are arranged in an array along a first direction and a second direction which are intersected with each other; both the first direction and the second direction are perpendicular to a third direction; and the third direction is a direction of a line connecting the sealed structure and the open structure.

Optionally, the memory device further includes a bit line, where the bit line extends along the first direction and is electrically connected to a memory unit via a second contact window and includes a first metal, where the first metal extends along the second direction and is electrically connected to another end of the switching device via a third contact window; and/or the bit line is on a side of the memory element away from the first contact window; and/or memory units arranged along the first direction are connected to a same bit line.

Optionally, the switching device is a diode switching device; and the switching device includes a first doped layer, electrically connected to the first contact window, and a second doped layer, on a side of the first doped layer away from the first contact window, where a doped type of the second doped layer is different from a doped type of the first doped layer.

Optionally, the switching device further includes an interconnect layer, where the interconnect layer is on a side of the second doped layer away from the first doped layer; and interconnect layers of switching devices of memory units arranged along the second direction extend to be connected with each other.

Optionally, the memory device further includes an interconnect activation layer. Along the second direction, the interconnect activation layer is on a side of the memory units arranged along the second direction; the interconnect layer extends to a position of the interconnect activation layer and is electrically connected to the interconnect activation layer; and a first metal is on a side of the interconnect activation layer away from the interconnect layer; and an end of the first metal along the second direction is electrically connected to the interconnect activation layer through a third contact window.

Optionally, the switching device is a transistor switching device; and the switching device includes a gate structure; and a first doped layer and a second doped layer, where along a plane perpendicular to a line connecting the switching device and the memory element, the first doped layer and the second doped layer are on two sides of the gate structure, and the first doped layer is electrically connected to the first contact window.

Optionally, second doped regions of the memory units arranged along the second direction are connected to a same first metal; and/or two memory units along the first direction are respectively a first memory unit and a second memory unit, a memory element of the first memory unit and a memory element of the second memory unit extend to be connected with each other, and a first metal electrically connected to the first memory unit and a first metal electrically connected to the second memory unit are respectively on two sides of a gate structure of a switching device of the first memory unit and a gate structure of a switching device of the second memory unit along the first direction.

Another aspect of the present disclosure provides a fabrication method of a memory device. The method includes forming a switching device; forming a first contact window, where one end of the first contact window is electrically connected to one end of the switching device; and forming a memory element, where the memory element is on a side of the first contact window away from the switching device and electrically connected to another end of the first contact window. The first contact window includes a conductive blocking layer, where the conductive barrier-layer encloses a hollow shell, an end of the hollow shell is a sealed structure configured with a bottom surface; the bottom surface of the sealed structure is electrically connected to a first device to-be-connected, another end of the hollow shell is an open structure not configured a bottom surface, and an end surface of the open structure is electrically connected to a second device to-be-connected; and a filling metal, where the filling metal fills a portion of the hollow shell enclosed by the conductive blocking layer, and one end of the first contact window is electrically connected to one end of the switching device.

Optionally, the method further includes forming a bit line, where the bit line extends along the first direction and is electrically connected to a memory unit via a second contact window; and forming a first metal, where the first metal extends along the second direction and is electrically connected to another end of the switching device via a third contact window.

Optionally, for forming the switching device, a diode switching device is formed; for forming the switching device, an interconnect activation layer is formed, where along a second direction, the interconnect activation layer is on a side of memory units arranged along the second direction; and after forming the first contact window and before forming the memory element, a first metal is formed, and the first metal is electrically connected to the interconnect activation layer through a third contact window.

Optionally, for forming the switching device, a transistor switching device is formed; and for forming the first contact window, the first contact window above the first doped layer and the third contact window above the second doped layer are formed.

Optionally, after forming the memory element, a first metal is formed; and after forming the first metal, a bit line is formed.

Compared with the existing technology, the technical solutions provided by the present disclosure may achieve at least the following beneficial effects.

In the present disclosure, the conductive barrier-layer encloses a hollow shell, an end of the hollow shell is a sealed structure configured with a bottom surface, the bottom surface of the sealed structure is electrically connected to a front-layer part to-be-connected (e.g., the first device to-be-connected), another end of the hollow shell is an open structure not configured a bottom surface, and an end surface of the open structure is electrically connected to a rear-layer part to-be-connected (e.g., the second device to-be-connected); and further includes a filling metal, where the filling metal fills a portion of the hollow shell enclosed by the conductive blocking layer. The filling metal only fills a portion of the hollow shell enclosed by the conductive blocking layer; on the side of the open structure, the filling metal is separated from the rear-layer part to-be-connected; and the contact area of the contact window and the rear-layer part to-be-connected is only the end surface of the conductive blocking layer. The contact area between the contact window and the rear-layer part to-be-connected may be relatively small, and the shape change of the contact window may be relatively small, which may reduce the contact area while simplifying the fabrication process, reduce the number of photomasks and process steps, lower process difficulty, and simultaneously reduce production costs.

In optional embodiments of the present disclosure, the contact window further includes an insulating material filled between the filling metal and the rear-layer part to-be-connected. The insulating material is filled between the filling metal and the subsequent part to-be-connected, which may effectively ensure the reliability and stability of the contact window, and fabrication yield.

### BRIEF DESCRIPTION OF THE DRAWINGS

The following drawings are merely examples for illustrative purposes according to various disclosed embodiments and are not intended to limit the scope of the present disclosure.

FIG. 1 illustrates a cross-sectional structural schematic of an exemplary memory unit.

FIG. 2 illustrates a structural schematic of an exemplary contact window according to various disclosed embodiments of the present disclosure.

FIG. 3 illustrates a three-dimensional structural schematic of an exemplary memory device according to various disclosed embodiments of the present disclosure.

FIG. 4 illustrates another three-dimensional structural schematic of an exemplary memory device according to various disclosed embodiments of the present disclosure.

FIG. 5 illustrates a cross-sectional structural schematic along an A1-A2 line of the exemplary memory device in FIG. 4.

FIGS. 6-16 illustrate structural schematics corresponding to certain stages of an exemplary fabrication method of a memory device according to some disclosed embodiments of the present disclosure.

FIGS. 17-29 illustrate structural schematics corresponding to certain stages of another exemplary fabrication method of a memory device according to other disclosed embodiments of the present disclosure.

FIG. 30 illustrates a flowchart of an exemplary fabrication method of an exemplary memory device according to various disclosed embodiments of the present disclosure.

### DETAILED DESCRIPTION

References are made in detail to exemplary embodiments of the disclosure, which are illustrated in accompanying drawings. Wherever possible, same reference numbers are used throughout accompanying drawings to refer to same or like parts.

A contact window, a memory unit, a memory device, and a fabrication method are provided in the present disclosure. The contact window includes a conductive blocking layer, where the conductive barrier-layer encloses a hollow shell, an end of the hollow shell is a sealed structure configured with a bottom surface, the bottom surface of the sealed structure is electrically connected to a front-layer part to-be-connected (e.g., the first device to-be-connected), another end of the hollow shell is an open structure not configured a bottom surface, and an end surface of the open structure is electrically connected to a rear-layer part to-be-connected (e.g., the second device to-be-connected); and further includes a filling metal. The filling metal fills a portion of the hollow shell enclosed by the conductive blocking layer.

From the background technology, it can be known that current method of reducing the contact area in existing technology may result in the problems of increased process complexity, higher processing costs and the like.

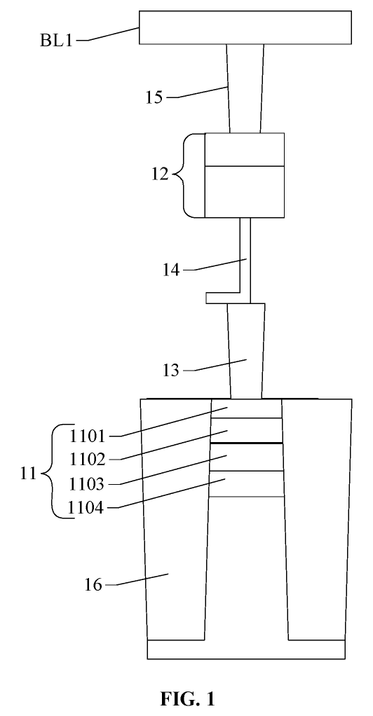

Referring to FIG. 1, FIG. 1 illustrates a cross-sectional structural schematic of an exemplary memory unit.

The memory unit may include a switching device 11; a memory element 12; a first contact window 13 between the switching device 11 and the memory element 12; and a blade electrode 14 between the first contact window 13 and the memory element 12, where an end of the blade electrode 14 may be electrically connected to the memory element 12, and another end blade electrode 14 may be electrically contacting the first contact window 13. The memory unit may further include a bit line BL1, another contact window 15 and an isolation structure 16. The switching device 11 may include a connection layer 1101, a first doped layer 1102, a second doped layer 1103, and an interconnect layer 1104.

The smaller the contact area between the memory element 12 and the switching device 11 is, the greater the current density between the memory element 12 and the switching device 11 is. Therefore, greater current density may more effectively drive the phase change material to undergo the phase change, thereby effectively reducing the energy consumption of the memory unit.

As shown in FIG. 1, by disposing the blade electrode 14 between the first contact window 13 and the memory element 12, the contact area may be reduced, and the current density may be increased. However, the formation of the blade electrode 14 may need multiple process steps such as deposition, etching and the like, and need a large number of photomasks and complex processes. Furthermore, disposing the blade electrode 14 may increase total height of the interconnect structure at the position of the memory unit; that is, the height of the interconnect structure may be the sum of the height of the first contact window 13 and the height of the blade electrode 14, which may have adverse effect on the connection of electrodes in the peripheral circuit region. Therefore, there is a need to introduce more photomasks and processes to overcome introduced adverse effect.

To address above-mentioned technical problem, the present disclosure provides a contact window, which is suitable for achieving electrical connection between a front-layer part to-be-connected (e.g., a first device to-be-connected) and a rear-layer part to-be-connected (a second device to-be-connected). The contact window may include a conductive blocking layer, where the conductive barrier-layer forms a hollow shell, an end of the hollow shell is a sealed structure configured with a bottom surface; the bottom surface of the sealed structure is electrically connected to a front-layer part to-be-connected, another end of the hollow shell is an open structure without a bottom surface, and an end surface of the open structure is electrically connected to a rear-layer part to-be-connected; and a filling metal, where the filling metal fills a portion of the hollow shell enclosed by the conductive blocking layer.

In the present disclosure, the filling metal only fills a portion of the hollow shell enclosed by the conductive blocking layer; on the side of the open structure, the filling metal is separated from the rear-layer part to-be-connected; and the contact area of the contact window and the rear-layer part to-be-connected is only the end surface of the conductive blocking layer. The contact area between the contact window and the rear-layer part to-be-connected may be relatively small, and the shape change of the contact window may be relatively small, which may reduce the contact area while simplifying the fabrication process, reduce the number of photomasks and process steps, lower process difficulty, and simultaneously reduce production costs.

In order to clearly illustrate above-mentioned described objectives, features, and advantages of the present disclosure, various embodiments of the present disclosure are described in detail with reference to accompanying drawings hereinafter.

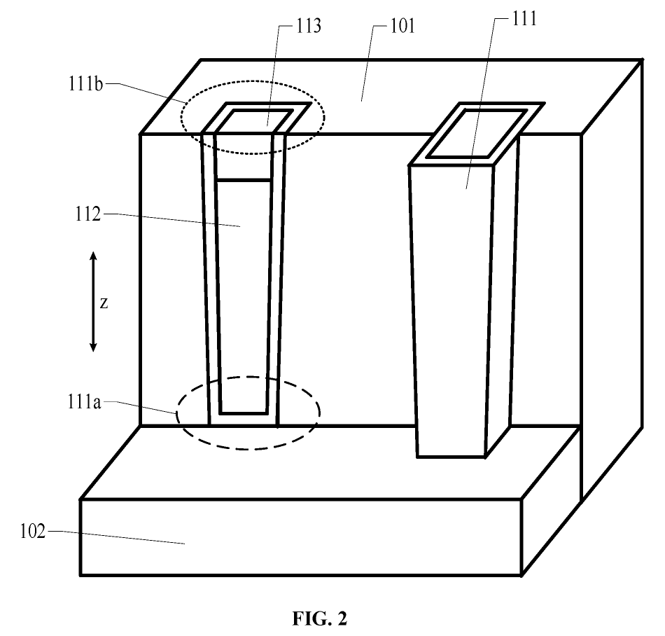

Referring to FIG. 2, FIG. 2 illustrates a structural schematic of an exemplary contact window according to various disclosed embodiments of the present disclosure.

The contact window may include a conductive barrier-layer 111, where the conductive barrier-layer 111 encloses a hollow shell, an end of the hollow shell is a sealed structure configured with a bottom surface, the bottom surface of the sealed structure is electrically connected to a front-layer part to-be-connected, another end of the hollow shell is an open structure without a bottom surface, and an end surface of the open structure is electrically connected to a rear-layer part to-be-connected; and further include a filling metal 112, where the filling metal 112 fills a portion of the hollow shell enclosed by the conductive barrier-layer 111. In one embodiment, a connection layer 102 may be below the conductive barrier-layer 111.

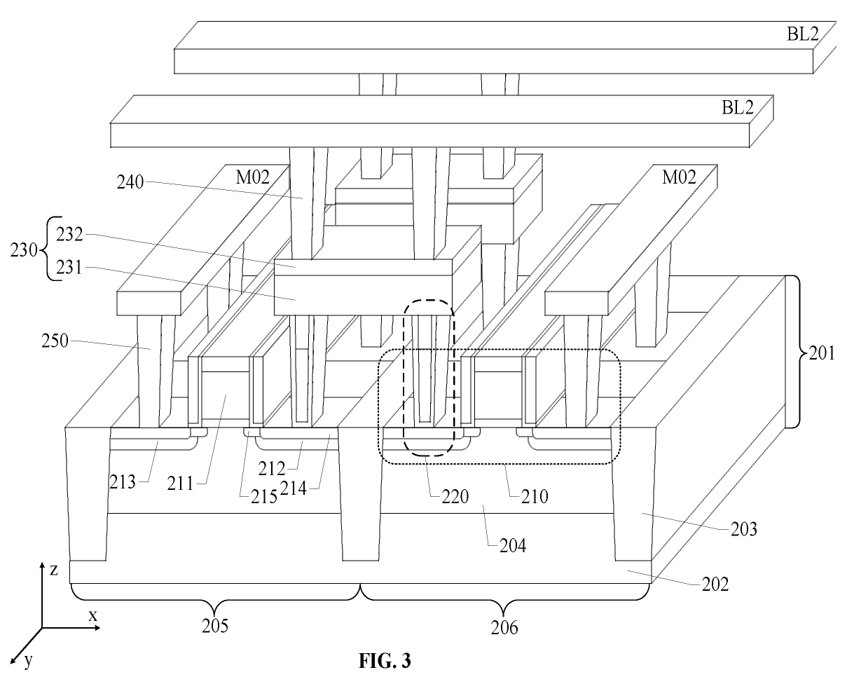

The front-layer part to-be-connected may include a first device to-be connected (e.g., a transistor, such as the first doped layer 212 in FIG. 3) connected to the contact window at a first side; and the rear-layer part to-be-connected may include a second device to-be-connected (e.g., a memory unit, such as the memory element 230 in FIG. 3) connected to the contact window at a second side, which may be opposite to the first side according to one embodiment of the present disclosure.

The technical solution of the contact window in embodiments of the present disclosure is described in detail below with reference to the accompanying drawings.

It should be noted that an second insulating material 101 may be configured between the front-layer part to-be-connected and the rear-layer part to-be-connected to achieve electrical insulation; and the contact window may pass through the second insulating material 101, thereby achieving electrical connection between the front-layer part to-be-connected and the rear-layer part to-be-connected.

The conductive barrier-layer 111 may be suitable to prevent the filling metal 112 from diffusing into the second insulating material 101; and the conductive barrier-layer 111 may be made of a conductor, and also suitable for achieving electrical connection between the front-layer part to-be-connected and the rear-layer part to-be-connected.

For example, as shown in FIG. 2, the conductive barrier-layer 111 may be configured as a shell wall to enclose the hollow shell. The end of the hollow shell facing toward the front-layer part to-be-connected may be a sealed structure 111a configured with the bottom surface (shown in the dashed-line circle in FIG. 2), and the bottom surface of the sealed structure 111a may be electrically connected to the front-layer part to-be-connected. For example, the bottom surface of the sealed structure 111a may be in contact with the front-layer part to-be-connected.

The end of the hollow shell facing toward the rear-layer part to-be-connected may be an open structure 111b without a bottom surface (as shown in the dotted-line circle in FIG. 2); and the end surface of the open structure 111b, that is, the end surface of the conductive barrier-layer 111 exposed on the side of the open structure 111b, may be electrically connected to the rear-layer part to-be-connected. For example, the end surface of the open structure 111b may be in electrical contact with the rear-layer part to-be-connected.

The hollow shell may be in electrical contact with the rear-layer part to-be-connected through the end surface of the open structure 111b. The area of the end surface of the open structure 111b may be relatively small, which may greatly reduce the contact area of electrical contact and effectively increase current density of electrical contact. Furthermore, the hollow shell enclosed by the conductive barrier-layer may be configured to achieve electrical connection, which may simplify the fabrication process, reduce fabrication difficulty, and effectively lower the production cost of the contact window.

In some embodiments of the present disclosure, the thickness of the conductive barrier-layer 111 may be uniform. The conductive barrier-layer 111 with uniform thickness may effectively improve the uniformity of current distribution in the conductive blocking layer, thereby enhancing reliability and stability.

In some embodiments, the thickness of the conductive barrier-layer 111 may be in the range of 1 nm to 20 nm. For example, the thickness of the conductive barrier-layer 111 may be the wall thickness of the hollow shell enclosed by the conductive barrier-layer 111. For example, the thickness of the conductive barrier-layer 111 may be the dimension along the third direction z of the bottom surface of the sealed structure 111a, where the third direction may be the direction of the line connecting the sealed structure and the open structure.

In some embodiments of the present disclosure, the conductive barrier-layer 111 may be made of a material including at least one of titanium nitride, tantalum nitride, titanium, tantalum, and ruthenium. In other embodiments of the present disclosure, the conductive barrier-layer may also be made of other conductive materials capable of preventing metal diffusion.

The filling metal 112 may fill the portion of the hollow shell enclosed by the conductive barrier-layer 111, thereby reducing the resistance of the electrical connection between the front-layer part to-be-connected and the rear-layer part to-be-connected.

The filling metal 112 may only fill a portion of the internal space of the hollow shell enclosed by the conductive barrier-layer 111 and may not fill remaining space of the hollow shell. In some embodiments, the filling metal 112 may fill the portion of the hollow shell which is enclosed by the conductive barrier-layer 111 and adjacent to the front-layer part to-be-connected.

For example, as shown in FIG. 2, the filling metal 112 may fill a portion of the space on the side of the sealed structure 111a in the hollow shell, and the filling metal 112 may be in direct contact with the bottom surface of the sealed structure 111a; and the filling metal 112 may not fill the portion of the space on the side of the open structure 112 in the hollow shell.

In some embodiments of the present disclosure, the ratio of the thickness of the filling metal 112 to the depth of the hollow shell may be less than 2/3. Herein, the depth of the hollow shell may be the dimension of the internal space of the hollow shell along the z-direction of the line connecting the front-layer part to-be-connected and the rear-layer part to-be-connected; and the thickness of the filling metal 112 may be the dimension of the filling metal 112 along the z-direction of the line connecting the front-layer part to-be-connected and the rear-layer part to-be-connected.

In some embodiments of the present disclosure, the filling metal 112 may be made of a material including tungsten. In other embodiments of the present disclosure, the filling metal 112 may also be made of a material including copper or aluminum.

In some embodiments of the present disclosure, the contact window may further include a first insulating material 113; and the first insulating material 113 may fill the space between the filling metal 112 and the rear-layer part to-be-connected. The first insulating material 113 may fill remaining space of the hollow shell, thereby avoiding direct contact between the filling metal 112 and the rear-layer part to-be-connected, ensuring controllable contact area between the contact window and the rear-layer part to-be-connected, and ensuring overall mechanical strength of the contact window.

In some embodiments, the surface of the first insulating material 113 facing toward the rear-layer part to-be-connected may be in contact with the rear-layer part to-be-connected. The first insulating material 113 and the filling metal 112 may fill entire internal space of the hollow shell; and one side of the first insulating material 113 may be in direct contact with the filling metal 112 and another side of the first insulating material 113 may be in direct contact with the rear-layer part to-be-connected.

In some embodiments, the thickness of the first insulating material 113 may be less than a half of the distance between the filling metal and the rear-layer part to-be-connected. The thickness of the first insulating material 113 may be the dimension of the first insulating material 113 along the third direction z. Appropriate thickness of the first insulating material 113 may effectively prevent direct contact between the filling metal 112 and the rear-layer part to-be-connected, thereby effectively ensuring the mechanical strength of overall structure of the contact window.

It should be noted that in some embodiments, the first insulating material 113 may completely fill remaining space of the hollow shell. In other embodiments of the present disclosure, the insulating material may partially fill remaining space of the hollow shell to form a gap between the insulating material and the rear-layer part to-be-connected. In still other embodiments of the present disclosure, no other material may be disposed between the filling metal and the rear-layer part to-be-connected, thereby forming a gap between the insulating material and the rear-layer part to-be-connected. Forming the gap on the side of the rear-layer part to-be-connected adjacent to the filling metal may effectively reduce the dielectric constant of the material between the rear-layer part to-be-connected and the filling metal, thereby being beneficial to improving the electrical performance of the contact window.

In some embodiments, the first insulating material 113 may be made of a material including silicon nitride. In other embodiments of the present disclosure, the first insulating material 113 may also be made of a material including silicon oxide, silicon oxynitride, or other suitable insulating materials.

Correspondingly, the present disclosure further provides a memory unit.

Referring to FIG. 3, FIG. 3 illustrates a three-dimensional structural schematic of an exemplary memory unit according to various disclosed embodiments of the present disclosure.

The memory unit may include a switching device 210; a first contact window 220, where the first contact window 220 is the contact window of the present disclosure, and an end of the first contact window 220 may be electrically connected to an end of the switching device 210; and a memory element 230, where the memory element 230 may be on the side of the first contact window 220 away from the switching device 210 and electrically connected to another end of the first contact window 220.

The technical solution of the memory unit in embodiments of the present disclosure is described in detail below with reference to the accompanying drawings.

The switching device 210 may be configured to select the memory unit, thereby realizing control operations such as writing, reading, erasing and the like of the memory unit.

In some embodiments of the present disclosure, the switching device 210 may be a transistor switching device; the switching device 210 may include a gate structure 211; and a first doped layer 212 and a second doped layer 213, where in the plane perpendicular to the line connecting the switching device 210 and the memory element 230, the first doped layer 212 and the second doped layer 213 may be on two sides of the gate structure 211, and the first doped layer 212 may be electrically connected to the first contact window 220.

The gate structure 211 may control the turn-on and turn-off of the channel of the transistor switching device.

In some embodiments of the present disclosure, the gate structure 211 may include a gate electrode; a gate dielectric layer below the gate electrode; and a gate spacer on the sidewall of the gate electrode.

As shown in FIG. 3, the memory unit may include a base substrate 201. The base substrate 201 may include a substrate 202; an isolation structure 203 in the substrate 202; and an active region 204 in the substrate 202 between adjacent isolation structures 203.

For example, the substrate 202 may be a silicon substrate, and the material of the substrate 202 may be silicon. For example, the material of the substrate 202 may be selected from monocrystalline silicon, polycrystalline silicon, or amorphous silicon. In other embodiments, the material of the substrate may also be selected from silicon, germanium, gallium arsenide, or silicon-germanium compounds; the substrate may also be selected from materials having an epitaxial layer or a silicon-on-epitaxy layer structure; and the substrate may also be made of other semiconductor materials.

The isolation structure 203 may be in the substrate 202 to improve leakage current. For example, a plurality of the isolation structures 203 may be arranged to be in parallel with each other along the first direction x, where the first direction x may be in parallel with the surface of the substrate 202. The material of the isolation structure 203 may be an insulating material. For example, the material of the isolation structure 203 may be silicon oxide or silicon nitride.

The active region 204 may be between two adjacent isolation structures 203, which may provide a basis for the formation of the switching device 201. For example, the active region 204 may be a P-type doped region. In other embodiments of the present disclosure, the active region may also be an N-type doped region.

The gate structure 211 may be on the base substrate 201. For example, the gate electrode may be on the active region 204 between adjacent isolation structures 203 in the base substrate 201; and the gate dielectric layer may be between the gate electrode and the active region 204.

In some embodiments of the present disclosure, the gate structure 211 may be a polysilicon gate structure, that is, the material of the gate electrode may be polysilicon; and the material of the gate dielectric layer may be silicon oxide. In other embodiments of the present disclosure, the gate structure may also be a metal gate structure, that is, the material of the gate electrode may be metal; and the gate dielectric layer may be made of a material including a high-k gate dielectric material.

The first doped layer 212 and the second doped layer 213 may be the source doped layer and the drain doped layer of the transistor switching device, respectively.

For example, the gate structure 211 may be on the active region 204 in the base substrate 201; and the first doped layer 212 and the second doped layer 213 may be in the active region 204 on two sides of the gate structure 211.

The first doped layer 212 and the second doped layer 213 may have same conductivity type. For example, the first doped layer 212 and the second doped layer 213 may both be P-type doped layers; and in other embodiments, the first doped layer and the second doped layer may also both be N-type doped layers.

The first doped layer 212 and the second doped layer 213 may be formed in the active region 204 by an ion implantation manner; and the first doped layer 212 and the second doped layer 213 may also be formed by other doped processes.

It should be noted that, as shown in FIG. 3, in some embodiments of the present disclosure, the switching device 210 may include a connection layer 214; and the connection layer 214 may be between the first doped layer 212 and the first contact window 220.

The connection layer 214 may be suitable to reduce the resistance of the electrical connection between the first doped layer 212 and the first contact window 220 of the switching device 210.

For example, the material of the connection layer 214 may be metal silicide. For example, the material of the connection layer 214 may be at least one of nickel silicide (NiSi), nickel-platinum silicide (NiPtSi), titanium silicide (TiSi2), and cobalt silicide (CoSi2).

The first contact window 220 may be configured to realize the electrical connection between the switching device 210 and the memory element 230.

The first contact window 220 may be the contact window of the present disclosure. The technical solution of the first contact window 220 refers to above-mentioned embodiments of the contact window, which may be not described in detail herein.

As shown in FIG. 3, the switching device 210 may be a transistor switching device. The first contact window 220 may be electrically connected to the first doped layer 212 of the switching device 210. The first doped layer 212 of the switching device 210 may be configured as the front-layer part to-be-connected which is electrically connected to one end of the sealed structure of the hollow shell enclosed by the conductive barrier-layer in the first contact window 220. For example, the bottom surface of the sealed structure may be in direct contact with the surface of the connection layer 214 on the first doped layer 212.

The first contact window 220 may extend along the direction z perpendicular to the surface of the base substrate 201. The line connecting the open structure and the sealed structure of the first contact window 220 may be in parallel with the direction z perpendicular to the surface of the base substrate 201.

The memory element 230 may be configured to store data.

The memory element 230 may be above the switching device 210 and electrically connected to the switching device 210 through the first contact window 220.

For example, the memory element 230 may be above the first doped layer 212 of the switching device 210. The memory element 230 may be configured as the rear-layer part to-be-connected which is electrically connected to one end of the open structure of the hollow shell enclosed by the conductive barrier-layer in the first contact window 220.

Only the end surface of the open structure of the hollow shell enclosed by the conductive barrier-layer may be electrically connected to the memory element 230. Therefore, the contact area between the first contact window 220 and the memory element 230 may be significantly small, which may effectively increase the current density of the electrical contact between the memory element 230 and the first contact window 220, and improve current heating efficiency and the data read/write efficiency of the memory element 230.

Furthermore, the shape of the first contact window 230 may have minimal variation, the fabrication process may be simple, the fabrication difficulty may be relatively low, the process may be achieved without adding additional photomasks, and production costs may be relatively low.

Moreover, by setting the first contact window 220 as the contact window of the present disclosure, there may be no need to set other interconnect structures to reduce the contact area of the electrical connection and increase the current density, thereby effectively simplifying the fabrication process of the memory unit and reducing fabrication costs.

In some embodiments of the present disclosure, the memory element 230 may be a phase-change memory element. For example, the memory element 230 may be a phase-change random access memory (PCRAM), that is, the memory unit may be a structure of one transistor plus one PCRAM (1T1PCRAM).

For example, as shown in FIG. 3, the memory element 230 may include a phase-change layer 231 which is electrically connected to the first contact window 220; and an upper-layer electrode 232 on the surface of the phase-change layer 231 away from the first contact window 220.

Under the Joule heating effect of the current transmitted through the first contact window 220, the phase-change layer 231 may change between a crystalline state and an amorphous state, thereby exhibiting different resistivities to achieve data storage.

For example, the phase-change layer 231 may be electrically connected to the first contact window 220. For example, the phase-change layer 231 may be in direct contact with the end surface of the open structure of the hollow shell which is enclosed by the conductive barrier-layer in the first contact window 220.

In the first contact window 220, only the end surface of the open structure of the hollow shell enclosed by the conductive barrier-layer may be electrically connected to the phase-change layer 231. The contact area may be significantly small, which may effectively increase the current density of the electrical contact, improve the current heating efficiency, and effectively reduce the energy consumption required for the change between the crystalline state and the amorphous state of the phase-change layer 231, thereby reducing the energy consumption of the memory unit.

The upper-layer electrode 232 may be configured to connect the phase-change layer 231 to an external circuit.

The upper-layer electrode 232 may be on the side of the phase-change layer 231 away from the first contact window 220 and electrically connected to the phase-change layer 231. For example, the upper-layer electrode 232 may be on the surface of the phase-change layer 231 away from the first contact window 220.

For example, the material of the upper-layer electrode 232 may be titanium nitride. In other embodiments, the material of the upper-layer electrode 232 may also be other conductive materials.

It should be noted that in above-mentioned embodiments, the switching device 210 in the memory unit may be a transistor switching device, and the memory unit may be a structure of one transistor plus one memory element, such as a structure of one transistor plus one phase-change memory unit (1T1PCRAM). In other embodiments of the present disclosure, the switching device may also be another type of switching device.

It should also be noted that in the memory unit, a dielectric material may be formed on the base substrate to achieve electrical isolation. For example, the dielectric material may fill the space between the gate structure 211, the first contact window 220, the second contact window 240, the third contact window 250, the first metal MO2, the bit line BL2, and the memory element 230. For display clarity, the dielectric material is not shown in FIG. 3.

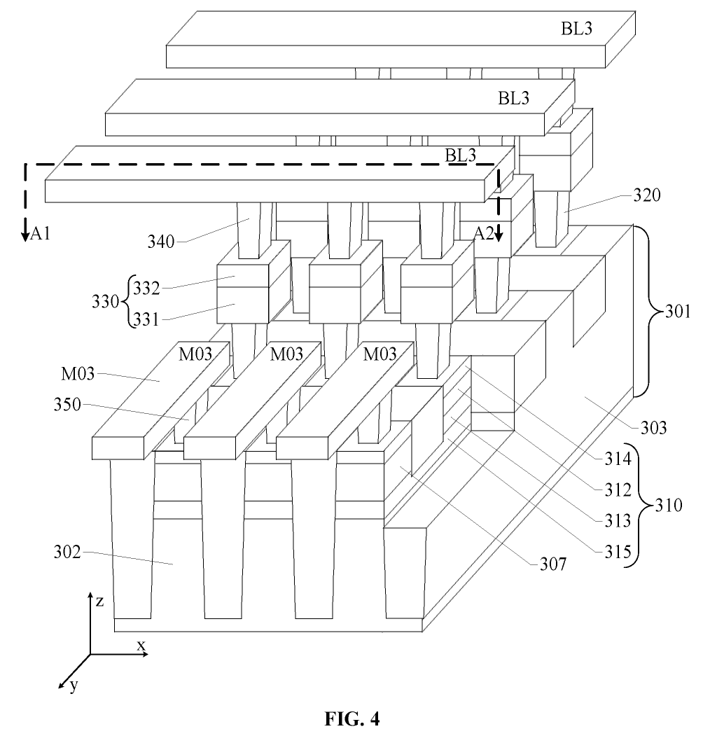

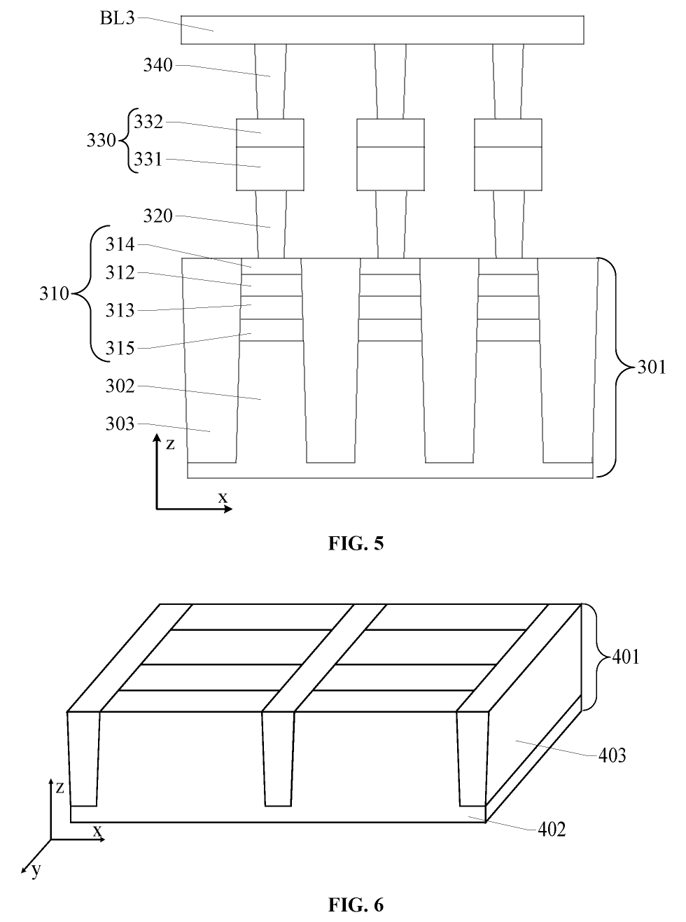

Referring to FIGS. 4-5, structural schematics of the memory units in other embodiments of the present disclosure are shown; FIG. 4 illustrates another three-dimensional structural schematic of an exemplary memory unit according to various disclosed embodiments of the present disclosure; and FIG. 5 illustrates a cross-sectional structural schematic of an exemplary memory unit along an A1-A2 line in FIG. 4.

The similarities with above-mentioned embodiments are not described in detail herein. Different from above-mentioned embodiments, in some embodiments of the present disclosure, the switching device 310 may be a diode switching device.

As shown in FIGS. 4-5, in some embodiments, the switching device 310 may include the first doped layer 312, which is electrically connected to the first contact window 320; and the second doped layer 313, which is on the side of the first doped layer 312 away from the first contact window 320, where the doped type of the second doped layer 313 may be different from the doped type of the first doped layer 312.

For example, the doped type of the second doped layer 313 may be different from the doped type of the first doped layer 312. For example, the first doped layer 312 may be a P-type doped layer, and the second doped layer 313 may be an N-type doped layer. The first doped layer 312 and the second doped layer 313 may be in contact with each other to form the diode.

In some embodiments of the example, the second doped layer 313 may be in the substrate 302 between adjacent isolation structures 303 in the base substrate 301; the first doped layer 312 may be on the surface of the second doped layer 313; and the surface of the first doped layer 312 may also have a connection layer 314.

In the first contact window 320, the bottom surface of the sealed structure of the hollow shell enclosed by the conductive barrier-layer may be in direct contact with the connection layer 314 on the surface of the first doped layer 312; and the end surface of the open structure of the hollow shell enclosed by the conductive barrier-layer may be in direct contact with the surface of the phase-change layer 331 of the memory element 330.

It should be noted that the memory element 330 may be a phase-change memory element, that is, the memory element may be a structure of one diode plus one phase change random access memory (1D1PCRAM). In other embodiments of the present disclosure, the memory element may also be other types of memory elements, such as resistive random access memory (RRAM), ferroelectric random access memory (FeRAM), or magnetic random access memory (MRAM).

It should also be noted that, in the memory unit, a dielectric material may be formed on the substrate to achieve electrical isolation. For example, the dielectric material may fill the space between the first contact window 320, the second contact window 340, the third contact window 350, the first metal MO3, the bit line BL3, and the memory element 330. For display clarity, the dielectric material is not shown in FIGS. 4-5.

Furthermore, the present disclosure further provides a memory device.

Referring to FIG. 3, a perspective structural schematic diagram of some embodiments of the memory device of the present disclosure is shown.

The memory device may include a memory array. The memory array may include memory units, the memory units may be the memory units of the present disclosure, and the memory units may be arranged in an array along the first direction x and the second direction y which are intersected with each other, where the first direction x and the second direction y are both perpendicular to the third direction z, the third direction z is the direction of the line connecting the sealed structure and the open structure.

The technical solution of the memory device in embodiments of the present disclosure is described in detail below with reference to the accompanying drawings.

The memory unit may be the memory unit of the present disclosure. The technical solution of the memory unit refers to above-mentioned embodiment of the contact window, which may be not described in detail herein.

For example, the first direction x and the second direction y which are intersected with each other may be both in parallel with the surface of the base substrate 201; the third direction z may be perpendicular to the surface of the base substrate 201; and the memory units may be arranged in an array in the base substrate 201 along the first direction x and the second direction y.

In the base substrate 201, the isolation structure 203 may extend along the second direction y, and multiple isolation structures 203 may be arranged parallel with each other along the first direction x. Furthermore, the isolation structure 203 may extend between adjacent memory units along the second direction y.

In some embodiments, in the memory unit, the switching device 210 may be a transistor switching device; the switching device 210 may include the gate structure 211, the first doped layer 212 and the second doped layer 213, where in the plane perpendicular to the third direction z, that is, in the plane in parallel with the surface of the base substrate 201, the first doped layer 212 and the second doped layer 213 may be on two sides of the gate structure 211, and the first doped layer 212 may be electrically connected to the first contact window 320; and the gate structures 211 of the switching devices 210 of the memory units arranged along the second direction y may extend to be connected with each other.

For example, as shown in FIG. 3, the gate structure 211 of the switching device 210 may extend along the second direction y and cross the isolation structure 203 between adjacent memory units along the second direction y; and the gate structures 211 of the switching devices 210 in adjacent memory units along the second direction y may be connected with each other.

In some embodiments of the present disclosure, the memory device may further include the first metal MO2; and the first metal MO2 may extend along the second direction y and be electrically connected to another end of the switching device 210 through the third contact window 250.

The first metal MO2 may be suitable to implement the connection between the memory unit and the external circuit.

The first metal MO2 may be above the second doped layer 213 of the switching device 210 and electrically connected to the second doped layer 213 of the switching device 210. For example, the first metal MO2 may extend along the second direction y and cross the second doped layers 213 of the switching devices 210 in multiple memory units.

The third contact window 250 may be above the second doped layer 213 of the switching device 210. For example, one end of the third contact window 250 may be in contact with the connection layer above the second doped layer 213, and another end of the third contact window 250 may be in contact with the first metal MO2.

In some embodiments, the second doped regions 213 of the memory units arranged along the second direction y may be connected to same first metal MO2. As shown in FIG. 3, the third contact window 250 may be configured above the second doped layer 213 of the switching device 210 in each memory unit; the third contact windows 250 above the second doped layers 213 of the switching devices in a plurality of memory units arranged along the second direction y may be in contact with same first metal MO2.

It should be noted that in some embodiments of the present disclosure, the shape of the first contact window 220 in the memory unit may be same as or similar to the shape of the third contact window 250, that is, the shape of the hollow shell enclosed by the conductive barrier-layer in the first contact window 220 may be same as or similar to the shape of the third contact window 250. Therefore, the fabrication process of the first contact window 220 may be similar to the fabrication process of the third contact window 250. The shape of the first contact window 230 may have minimal variation, the fabrication process may be simple, the fabrication difficulty may be relatively low, the process may be achieved without adding additional photomasks, and production costs may be relatively low.

Referring to FIG. 3, in some embodiments of the present disclosure, the memory device may further include the bit line BL2; the bit line BL2 may extend along the first direction x; and the bit line BL2 may be electrically connected to the memory unit through the second contact window 240.

The bit line BL2 may be suitable to implement the connection between the memory unit and the external circuit.

In some embodiments, the bit line BL2 may be on the side of the memory element 230 away from the first contact window 320. The first contact window 232 may be below the memory element 230; and the bit line BL2 may be above the memory element 230 and electrically connected to the upper-layer electrode 232 of the memory element 230. For example, the bit line BL2 may extend along the first direction x and cross the memory elements 230 of multiple memory units.

The second contact window 240 may be on the upper-layer electrode 232 of the memory element 230. For example, one end of the second contact window 240 may be in contact with the upper-layer electrode 232 of the memory element 230, and another end of the second contact window 240 may be in contact with the bit line BL2.

In some embodiments, the memory units arranged along the first direction x may be connected to same bit line BL2. As shown in FIG. 3, at least one second contact window 240 may be configured on the memory element 230 in the memory unit; and the second contact windows on the memory elements 230 of the plurality of memory units arranged along the first direction x may be in contact with same bit line BL2.

It should be noted that in some embodiments of the present disclosure, the shape of the first contact window 220 in the memory unit may be same as or similar to the shape of the second contact window 240; that is, the shape of the hollow shell surrounded by the conductive barrier-layer in the first contact window 220 may be same as or similar to the shape of the second contact window 240. Therefore, the fabrication process of the first contact window 220 may be similar to the fabrication process of the second contact window 240. The shape of the first contact window 230 may have minimal variation, the fabrication process may be simple, the fabrication difficulty may be relatively low, the process may be achieved without adding additional photomasks, and production costs may be relatively low.

It should also be noted that, in some embodiments, the switching device 210 in the memory unit may be a transistor switching device; the first doped layer 212 and the second doped layer 213 of the switching device 210 may be on two sides of the gate structure 211 along the first direction x; and the memory elements of two adjacent memory units along the first direction x may extend to be connected with each other.

For example, in some embodiments, two memory units along the first direction x may be the first memory unit 205 and the second memory unit 206; the memory element 230 of the first memory unit 205 and the memory element 230 of the second memory unit 206 may extend to be connected with each other; the first metal MO2 electrically connected to the first memory unit 205 and the first metal MO2 electrically connected to the second memory unit 206 may be respectively located on two sides of the gate structure 211 of the switching device 210 of the first memory unit 205 and the gate structure 211 of the switching device 210 of the second memory unit 206 along the first direction x.

As shown in FIG. 3, the first memory unit 205 and the second memory unit 206 may be arranged adjacent to each other along the first direction x; in the first memory unit 205, the first doped layer 212 may be on the side of the gate structure 211 adjacent to the second memory unit 206, and the second doped layer 213 may be on the side of the gate structure 211 away from the second memory unit 206; and in the second memory unit 206, the first doped layer 212 may be on the side of the gate structure 211 adjacent to the first memory unit 205, and the second doped layer 213 may be on the side of the gate structure 211 away from the first memory unit 205.

One first metal M02 may be above the second doped layer 213 of the first memory unit 205 and electrically connected to the second doped layer 213 of the first memory unit 205; and one first metal M02 may be above the second doped layer 213 of the second memory unit 206 and electrically connected to the second doped layer 213 of the second memory unit 206. Therefore, the first metal M02 electrically connected to the second doped layer 213 of the first memory unit 205 may be on the side of the gate structure 211 of the first memory unit 205 away from the second memory unit 206; and the first metal M02 electrically connected to the second doped layer 213 of the second memory unit 206 may be on the side of the gate structure 211 of the second memory unit 206 away from the first memory unit 205.

In the first memory unit 205, the phase-change layer 231 and the upper-layer electrode 232 of the memory element 230 may both extend toward the second memory unit 206; in the second memory unit 206, the phase-change layer 231 and the upper-layer electrode 232 of the memory element 230 may both extend toward the first memory unit 205; and the phase-change layer 231 and the upper-layer electrode 232 of the memory element 230 in the first memory unit 205 may be integrally connected to the phase-change layer 231 and the upper-layer electrode 232 of the memory element 230 in the second memory unit 206.

It should be noted that in above-mentioned embodiments, the memory unit may be a structure of one transistor plus one memory element, for example, a structure of one transistor plus one phase-change memory unit (1T1PCRAM). In other embodiments of the present disclosure, the switching device may also be another type of switching device.

Referring to FIGS. 4-5, structural schematics of the memory devices in some other embodiments of the present disclosure are shown; FIG. 4 illustrates another three-dimensional structural schematic of an exemplary memory device according to various disclosed embodiments of the present disclosure; and FIG. 5 illustrates a cross-sectional structural schematic of an exemplary memory device along an A1-A2 line in FIG. 4.

The similarities with above-mentioned embodiments are not described in detail herein. Different from above-mentioned embodiments, in some embodiments of the present disclosure, the switching device 310 in the memory unit may be a diode switching device.

As shown in FIGS. 4-5, in some embodiments, the switching device 310 may include the first doped layer 312, which is electrically connected to the first contact window 320; and the second doped layer 313, which is on the side of the first doped layer 312 away from the first contact window 320, where the doped type of the second doped layer 313 may be different from the doped type of the first doped layer 312.

For example, as shown in FIG. 3, the second doped layer 313 and the first doped layer 312 may be stacked sequentially along the third direction z.

In some embodiments, the switching device 310 may further include an interconnect layer 315; the interconnect layer 315 may be on the side of the second doped layer 313 away from the first doped layer 312; and the interconnect layers 315 of the switching devices 310 of the memory units arranged along the second direction y may extend to be connected with each other.

For example, the interconnect layer 315 may be in the base substrate 301 below the second doped layer 313, and the second doped layer 313 may be on the surface of the interconnect layer 315; and the bottom surface of the second doped layer 313 may be in contact with the surface of the interconnect layer 315. For example, the interconnect layer 315 may extend along a second direction y; and the interconnect layers 315 of the memory units arranged along the second direction y may be connected with each other to form a single piece.

In some embodiments, the memory device may further include an interconnect activation layer 307; along the second direction y, the interconnect activation layer 307 may be on the side of the memory units arranged along the second direction y; the interconnect layer 315 may extend to the position of the interconnect activation layer 307 and be electrically connected to the interconnect activation layer 307; the first metal MO3 may be on the side of the interconnect activation layer 307 away from the interconnect layer 315; and one end of the first metal MO3 along the second direction y may be electrically connected to the interconnect activation layer 307 through the third contact window 350.

For example, the interconnect activation layer 307 may be on the side of a column of memory units arranged along the second direction y. Each column of memory units arranged along the second direction y may be configured with the interconnect activation layer 307. Different interconnect activation layers 307 may be configured on same side of different columns of memory units arranged along the second direction y.

Furthermore, the interconnect layer 315 may extend to the position of the interconnect activation layer 307 and be electrically connected to the interconnect activation layer 307. For example, the interconnect activation layer 307 may be on the surface of the extending interconnect layer 315 and in contact with the surface of the interconnect layer 315.

For example, in one column of memory units arranged along the second direction y, the interconnect layers 315 of the switching devices 310 of different memory units may extend to be connected with each other, and extend to a side of the column of memory units; and the interconnect activation layer 307 may be on the surface of the interconnect layer 315 extending to the side of the column of memory units.

It should be noted that the interconnect activation layer 307 may be on the surface of the extending interconnect layer 315, and on same layer as the stacked layer of the second doped layer 313 and the first doped layer 312 of the switching device 310.

In some embodiments, the first metal MOS may be on the side of the interconnect activation layer 307 away from the interconnect layer 315; and one end of the first metal MOS along the second direction y may be electrically connected to the interconnect activation layer 307 through the third contact window 350.

For example, the first metal MOS may be on the interconnect activation layer 307 and electrically connected to the interconnect activation layer 307 through the third contact window 350. As shown in FIG. 4, one end of the third contact window 350 may be in contact with the connection layer on the surface of the interconnect activation layer 307; another end of the third contact window 350 may be in contact with the first metal MOS.

The first metal MOS may extend, along the second direction y, from the top direction of the interconnect activation layer 307 to the direction away from multiple memory units; and one end of the first metal MOS adjacent to the memory unit may be electrically connected to the third contact window 350.

Referring again to FIGS. 4-5, in the memory device, the bit line BL3 may be on the side of the memory element 330 away from the first contact window 320 and electrically connected to the upper-layer electrode 332 of the memory element 330 through the second contact window 340.

The plurality of memory units arranged along the first direction x may be connected to same bit line BL3 extending along the first direction x. The surfaces of the upper-layer electrodes 332 of the memory elements 330 in the plurality of memory units arranged along the first direction x may be configured with the second contact windows 340; and another end of each of the plurality of second contact windows 340 may be in contact with same bit line BL3 extending along the first direction x.

Correspondingly, the present disclosure further provides a fabrication method of the memory device.

FIGS. 6-16 illustrate structural schematics corresponding to certain stages of an exemplary fabrication method of a memory device according to some disclosed embodiments of the present disclosure.

The fabrication method may include forming the switching device; forming the first contact window, where the first contact window is the contact window of the present disclosure, an end of the first contact window may be electrically connected to an end of the switching device; and forming the memory element, where the memory element may be on the side of the first contact window away from the switching device, and electrically connected to another end of the first contact window.

The technical solution of the memory device in embodiments of the present disclosure is described in detail below with reference to the accompanying drawings.

In some embodiments, the fabrication method of the present disclosure is suitable for fabricating the memory device of the present disclosure. The technical solution of the fabrication method refers to above-mentioned embodiments of the memory device, which may be not described in detail in the present disclosure.

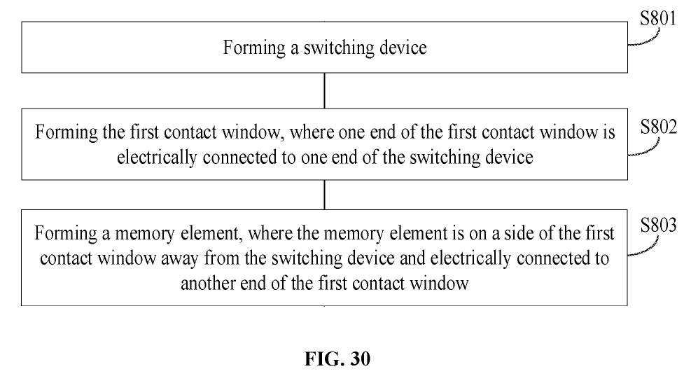

Referring to FIGS. 6-10, firstly, a switching device 410 may be formed (as shown in FIG. 10 and S801 of FIG. 30).

In some embodiments of the present disclosure, for forming the switching device 410, a transistor switching device 410 may be formed, that is, the switching device 410 may be the transistor switching device. Forming the switching device 410 may be a logic front-end-of-line transistor process.

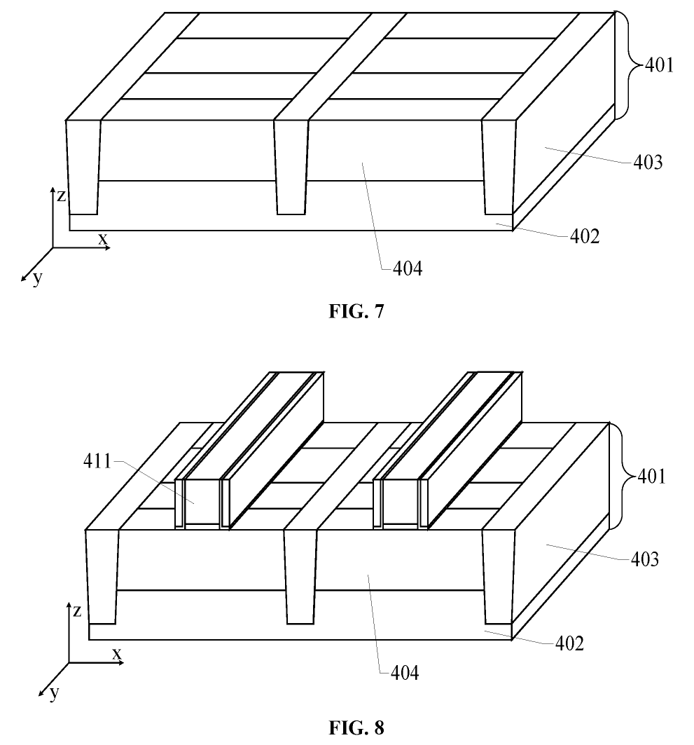

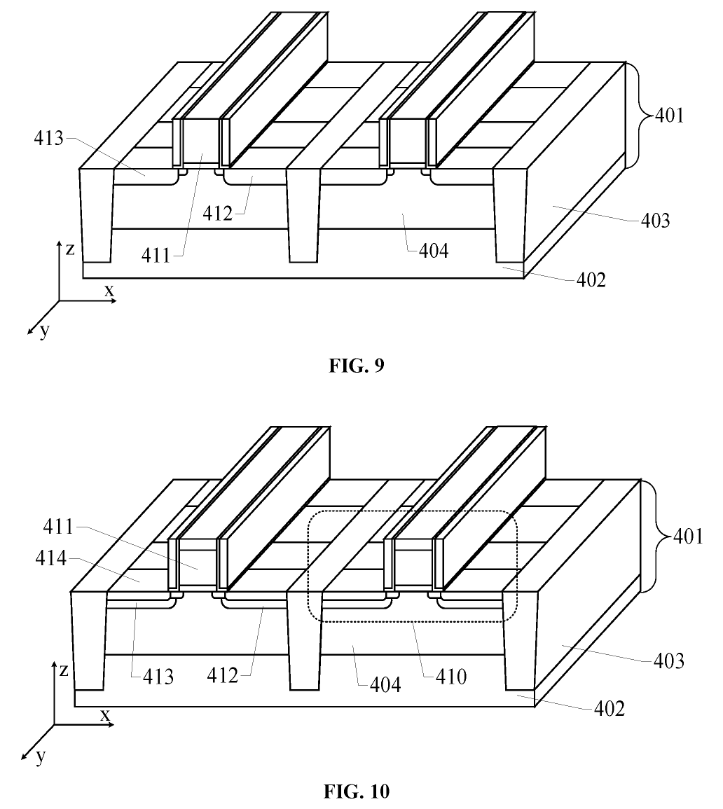

In some embodiments, forming the switching device 410 may be a standard CMOS process. Forming the switching device 410 may include forming a base substrate 401 as shown in FIG. 6; forming an active region 404 in the base substrate 401 as shown in FIG. 7; forming a gate structure 411 on the active region 404 as shown in FIG. 8; forming a first doped layer 412 and a second doped layer 413 in the active regions 404 on two sides of the gate structure 411 as shown in FIG. 9; and respectively forming connection layers 414 on the first doped layer 412 and the second doped layer 413 as shown in FIG. 10.

For example, as shown in FIG. 6, forming the base substrate 401 may include providing a substrate 402; and forming an isolation structure 403 in the substrate 402. Forming the isolation structure 403 in the substrate 402 may include etching the substrate 402 to form an isolation opening in the substrate 402; depositing a dielectric material into the isolation opening, where the dielectric material fills the isolation opening and covers the surface of the substrate 402; and planarizing the dielectric material to form the isolation structure 403 with a top surface coplanar with the surface of the substrate 402.

For example, as shown in FIG. 7, forming the active region 404 in the base substrate 401 may include performing ion-doping on the substrate 402 between the isolation structures 403 to form the active region 404. For example, ion-doping may be performed on the substrate 402 between the isolation structures 403 by an ion implantation manner; and in other embodiments, the active region 404 may also be formed by other ion-doping manners.

For example, as shown in FIG. 8, forming the gate structure 411 on the active region 404 may include forming a gate dielectric material and a gate electrode material on the base substrate 401; patterning the gate dielectric material and the gate electrode material to form a gate dielectric layer and a gate electrode; and forming a spacer structure on the sidewalls of the gate dielectric layer and the gate electrode, where the gate structure may include the first spacers on the surfaces of the sidewalls of the gate electrode and the gate dielectric layer and the second spacers on the sidewalls of the first spacers, and the first spacer may further extend between the second spacer and the base substrate 401.

For example, as shown in FIG. 9, forming the first doped layer 412 and the second doped layer 413 in the active regions 404 on two sides of the gate structure 411 may include lightly doping two sides below the gate structure 411 to form a lightly doped drain (LDD); after forming the lightly doped drain, forming the first doped layer 412 and the second doped layer 413 in the active regions 404 on two sides of the gate structure 411, respectively.

For example, as shown in FIG. 10, forming a connection layer 414 on the first doped layer 412 and the second doped layer 413 may include forming a metal layer material on the surfaces of the base substrate 401 and the gate structure 411; and performing an annealing process to react the metal material with silicon to form the connection layer 414, where the connection layer 414 may be on the surfaces of the first doped layer 412, the second doped layer 413, and the gate electrode, respectively.

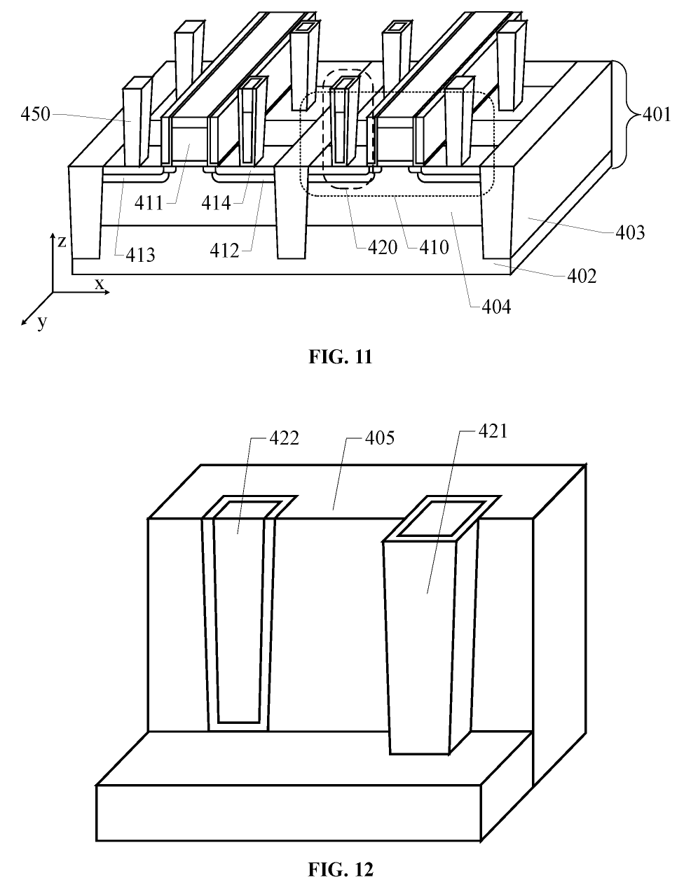

After forming the switching device 410, referring to FIG. 11, the first contact window 420 may be formed; the first contact window 420 may be the contact window of the present disclosure; and an end of the first contact window 420 may be electrically connected to an end of the switching device 410 (e.g., in S802 of FIG. 30).

It should be noted that, after forming the switching device 410 and before forming the first contact window 420, the fabrication method may further include forming the dielectric material on the base substrate 401, where the dielectric material may cover the base substrate 401 and the switching device 410. For display clarity, the dielectric material is not shown in FIGS. 11-16. Therefore, for forming the first contact window 420, the first contact window 420 may pass through the dielectric material.

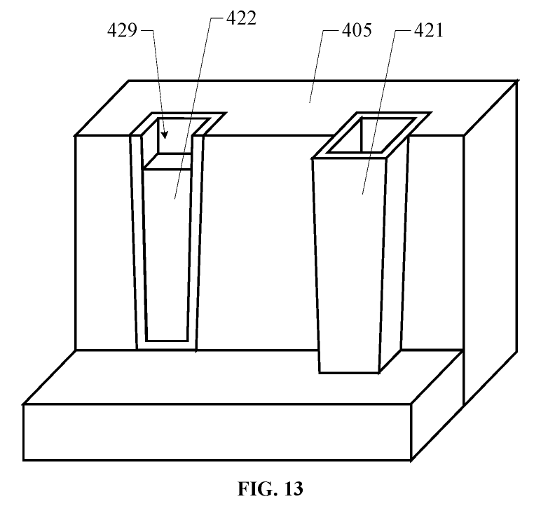

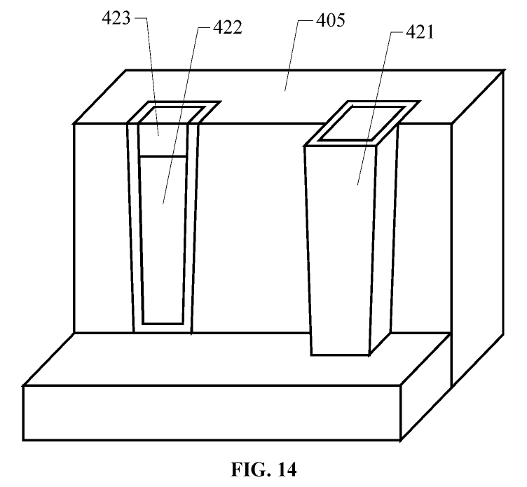

In some embodiments of the present disclosure, as shown in FIGS. 12-14, forming the first contact window 420 may include, as shown in FIG. 12, forming a contact opening passing through the dielectric material 405, where the bottom of the contact opening may expose the connection layer 414 on the first doped layer 412 (as shown in FIG. 11); forming a conductive barrier-layer 421 covering the sidewalls and bottom of the contact opening; and forming a filling metal 422 in the contact opening of the conductive barrier-layer 421 formed on corresponding sidewalls, where the top surface of the blocking layer 421 may be coplanar with the surface of the conductive barrier-layer 421 covering the sidewalls of the contact opening; as shown in FIG. 13, etching back the filling metal 422, where the top surface of remaining filling metal 422 may be lower than the top surface of the conductive barrier-layer 421 covering the sidewalls of the contact opening, and the top surface of remaining filling metal 422 and the conductive barrier-layer 421 covering the sidewalls of the contact opening may enclose a remaining opening 429 on remaining filling metal 422; and as shown in FIG. 14, filling an insulating material 423 into the remaining opening 429, where the top surface of the insulating material 423 may be coplanar with the top surface of the conductive barrier-layer 421 covering the sidewalls of the contact opening.

For forming the contact opening, the contact opening may be formed by a photolithography (i.e., exposure and development) and etching manner.

The conductive barrier-layer 421 may be formed by one of the following deposition manners, including atomic layer deposition, chemical vapor deposition, physical vapor deposition, and other film deposition manners.

For forming the filling metal 422, the filling metal 422 may be formed by one of the deposition manners including atomic layer deposition, chemical vapor deposition, physical vapor deposition, and other material deposition manners. For example, forming the filling metal 422 may include depositing a metal material in the contact opening of the conductive barrier-layer 421 formed on corresponding sidewalls, where the metal material may also cover the top surface of the dielectric material 405; removing the metal material higher than the top surface of the dielectric material 405, and forming the filling metal 422 with top surface coplanar with the top surface of the conductive barrier-layer 421 covering the sidewalls of the contact opening, where the metal material higher than the top surface of the dielectric material 405 may be removed by at least one of etching and planarization.

In filling the insulating material 423, the insulating material may be formed in the remaining opening 429 by one of the deposition manners including atomic layer deposition, chemical vapor deposition, and physical vapor deposition, where the insulating material may also cover the top surface of the dielectric material 405; and the insulating material higher than the top surface of the dielectric material 405 may be then removed, and the insulating material 423 with top surface coplanar with the top surface of the conductive barrier-layer 421 covering the sidewalls of the contact opening may be formed. The insulating material higher than the top surface of the dielectric material 405 may be removed by at least one of etching and planarization.

Referring to FIG. 11, in some embodiments of the present disclosure, for forming the first contact window 420, the first contact window 420 above the first doped layer 412 and the third contact window 450 above the second doped layer 413 may be formed.

The first contact window 420 and the third contact window 450 may be formed in same process, and the fabrication process of the first contact window 420 may be realized without additional photomasks, thereby effectively reducing the difficulty and cost of forming the first contact window 420.

For example, forming the first contact window 420 above the first doped layer 412 and the third contact window 450 above the second doped layer 413 may include forming a plurality of contact openings passing through the dielectric material, where the bottoms of a part of the contact openings may expose the bottom of the connection layer 414 on the first doped layer 412, and the bottoms of a part of the contact openings may expose the bottom of the connection layer 414 above the second doped layer 413; forming the conductive barrier-layer in each contact opening, where the conductive barrier-layer may cover the sidewall and bottom of the contact opening; and forming the filling metal in the contact opening of the conductive barrier-layer formed on corresponding sidewall, where the top surface of the filling metal may be coplanar with the top surface of the conductive barrier-layer covering the sidewall of the contact opening, and the conductive barrier-layer and the filling metal on the connection layer 414 at the surface of the second doped layer 413 may be suitable to form the third contact window 450.

A protective layer may be formed on the third contact window 450 and expose the filling metal on the connection layer 414 at the surface of the first doped layer 412; after forming the protective layer, in etching back the filling metal 422, only the filling metal on the connection layer 414 on the surface of the first doped layer 412 may be etched back to form remaining opening 429; and the insulating material 423 may be filled into the remaining opening 429 to form the first contact window 420. Etching back the filling metal 422 may be performed using a photomask-free etching manner.

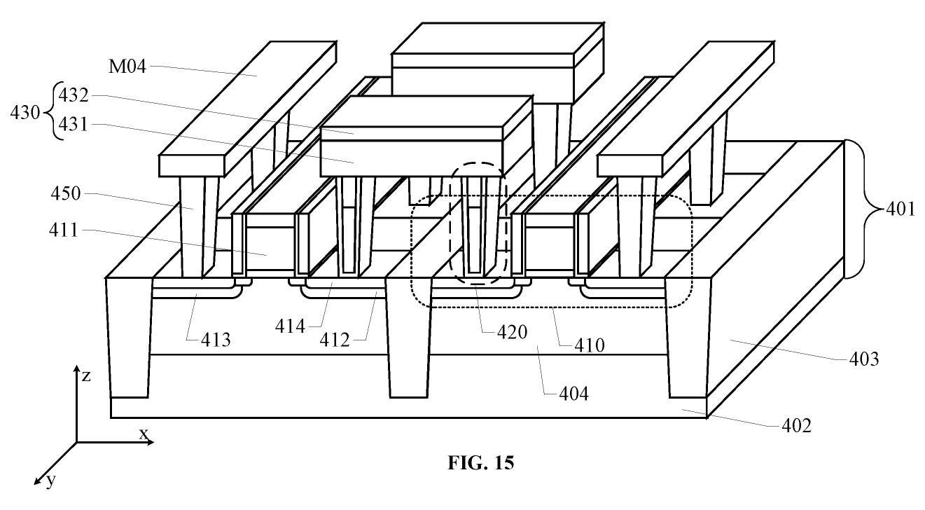

Next, referring to FIG. 15, the memory element 430 may be formed; the memory element 430 may be on the side of the first contact window 420 away from the switching device 410 and electrically connected to another end of the first contact window 420 (e.g., in S803 of FIG. 30).

For example, forming the memory element 430 may include forming a phase-change layer 431 on the first contact bed 420; and forming an upper-layer electrode 432 on the phase-change layer 431. For example, at least one step for forming the phase-change layer 431 and the upper-layer electrode 432 may be achieved through a combination of material deposition and patterning.

As shown in FIG. 15, in some embodiments of the present disclosure, the fabrication method may further include forming the first metal MO4, where the first metal MO4 may extend along the second direction y and electrically connected to another end of the switching device 410 through the third contact window 450.

Forming the first metal MO4 may be achieved through manners including photolithography, etching, and material deposition. For example, forming the first metal MO4 may include forming a trench in the dielectric material, where the bottom of the trench exposing the third contact window 450; and forming the first metal MO4 in the trench.

Forming the first metal MO4 in the trench may include filling the trench with the metal material covering the top surface of the dielectric material; and removing the metal material higher than the top surface of the dielectric material to form the first metal MO4 in the trench. For example, the metal material higher than the top surface of the dielectric material may be removed by etching or planarization.

It should be noted that in some embodiments, the first metal MO4 may be formed after the memory element 430 is formed; and in other embodiments, the memory element may be formed after the first metal is formed.

It should also be noted that after the memory element 430 and the first metal MO4 are formed, the dielectric material may be formed on the memory element 430 and the first metal MO4. The dielectric material is not shown in FIG. 15 for display clarity.

In some embodiments of the present disclosure, the fabrication method may further include forming the bit line BL4, where the bit line BL4 may extend along the first direction x and electrically connected to the memory unit through the second contact window 440.

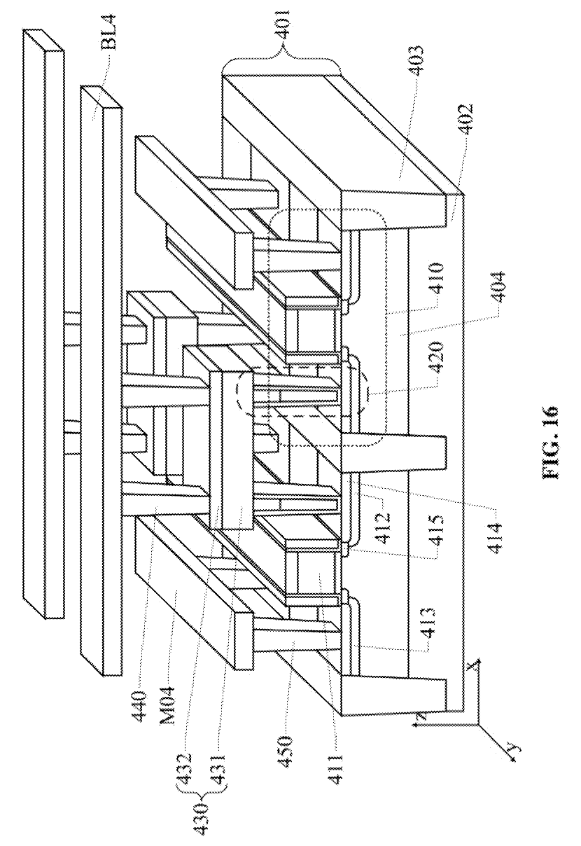

It should be noted that the dielectric material may be formed on the memory element 430 and the first metal MO4. The dielectric material is not shown in FIG. 16 for display clarity.

As shown in FIG. 16, the second contact window 440 passing through the dielectric material may be formed before the bit line BL4 is formed. For example, forming the second contact window 440 may include forming the contact opening passing through the dielectric material, where the bottom of the contact opening may expose the upper-layer electrode 432 of the memory element 430; and forming the second contact window 440 in the contact opening.

Forming the bit line BL4 may be achieved through manners including photolithography, etching, and material deposition. For example, forming the bit line BL4 may include forming the trench in the dielectric material, where the bottom of the trench may expose the second contact window 440; and forming the bit line BL4 in the trench.

Forming the bit line BL4 in the trench may include filling the trench with the metal material, where the metal material may cover the top surface of the dielectric material; and removing the metal material higher than the top surface of the dielectric material and forming the bit line BL4 in the trench. For example, the metal material higher than the top surface of the dielectric material may be removed by an etching or planarization manner.

It should be noted that in above-mentioned embodiments, the switching device 410 may be a transistor switching device; and the switching device 410 may be formed using a front-end-of-line transistor process. In other embodiments of the present disclosure, the switching device may be another type of switching device and formed using other processes.

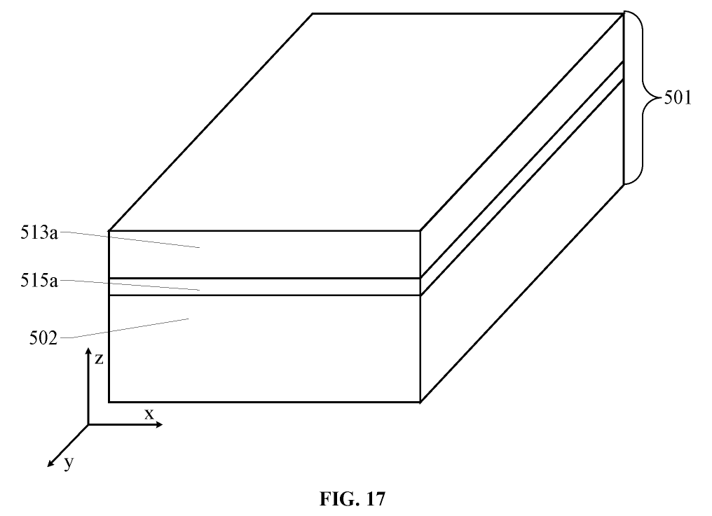

Referring to FIGS. 17-29, FIGS. 17-29 illustrate structural schematics corresponding to certain stages of another exemplary fabrication method of a memory device according to other disclosed embodiments of the present disclosure.

The similarities with above-mentioned embodiments are not described in detail herein. Different from above-mentioned embodiments, in some embodiments of the present disclosure, for forming the switching device, the diode switching device may be formed; and the switching device may be formed using a dual-channel diode process.

Referring to FIGS. 17-23, a switching device 510 may be formed.

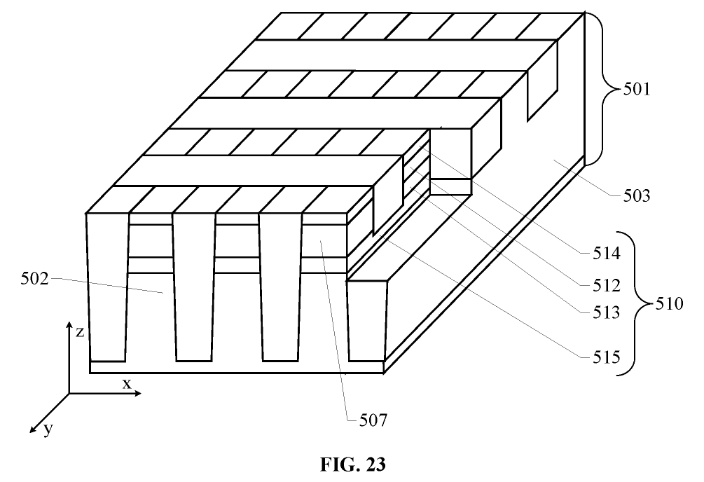

In some embodiments, the switching device 510 may be formed using a dual-channel diode process. Forming the switching device 510 may include forming a substrate 501 as shown in FIGS. 17-20; forming the second doped layer 513 and the first doped layer 512 as shown in FIG. 21; and forming a connection layer 514 on the first doped layer 512 as shown in FIG. 23.

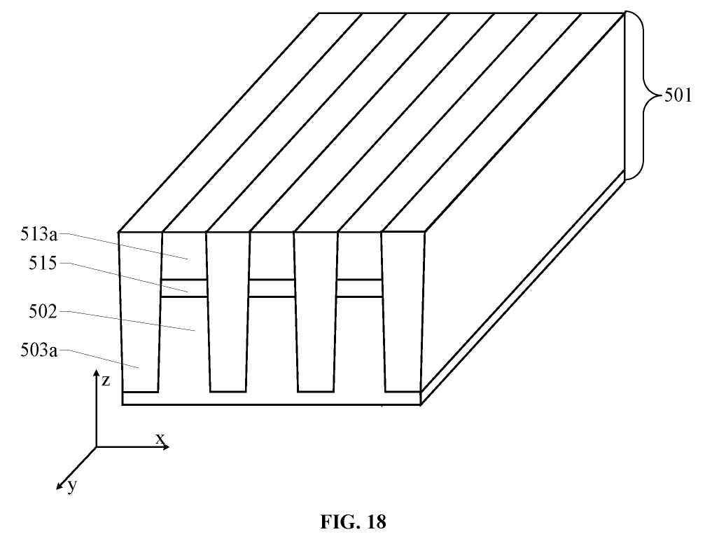

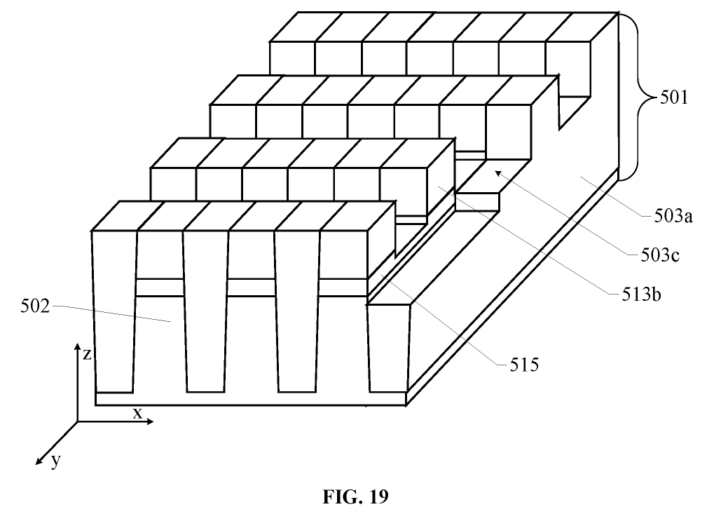

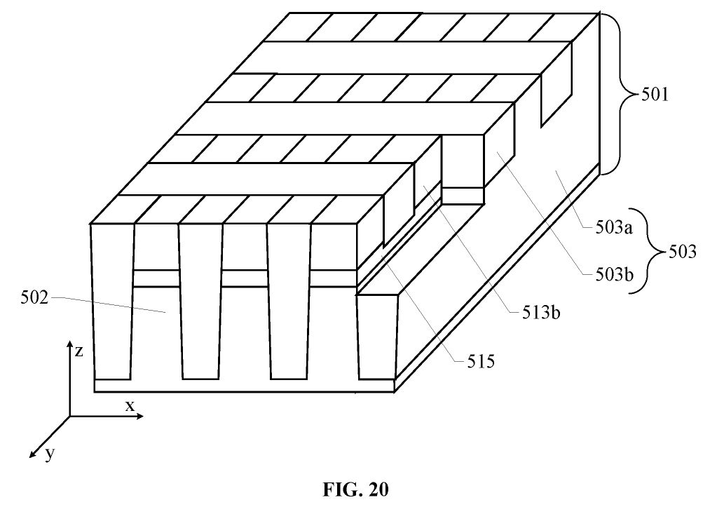

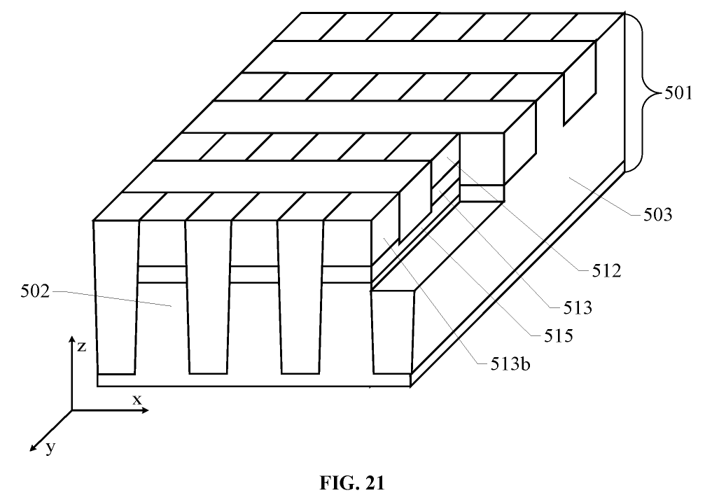

For example, forming the substrate 501 may include providing a substrate 502 as shown in FIG. 17; forming a first prefabricated layer 515a and a second prefabricated layer 513a on the first prefabricated layer 515a in the substrate; and forming a deep trench isolation structure 503a in the substrate 502 as shown in FIG. 18, where the deep trench isolation structure 503a may extend along the second direction y, and a plurality of deep trench isolation structures 503a may be arranged in parallel along the first direction x, and the first prefabricated layer 515a between adjacent deep trench isolation structures 503a may be suitable for forming an interconnect layer 515; forming a second trench 503c extending along the first direction x in the second prefabricated layer 513a as shown in FIG. 19, where the bottom of the second trench 503c may expose the interconnect layer 515, a plurality of second trenches 503c may be in parallel with each other along the second direction y, and the second prefabricated layer 513a between adjacent second trenches 503c may be suitable for forming the second prefabricated layer 513b; forming the shallow trench isolation structure 503b in the second trench 503c as shown in FIG. 20, where the shallow trench isolation structure 503b and the deep trench isolation structure 503a may be suitable for forming an isolation structure 503; and forming the first doped layer 512 in the second prefabricated layer 513b as shown in FIG. 21, where remaining portion of the second prefabricated layer 513b below the first doped layer 512 may be suitable for forming the second doped layer 513. In some embodiments, each of the deep trench isolation structure 503a and the shallow trench isolation structure 503b may include corresponding precursors (e.g., high-purity silicon oxide/silicon nitride precursors) used for filling trenches through, e.g., CVD/ALD processes, to achieve high electrical insulation of the deep/shallow isolation structures.

Forming the first prefabricated layer 515a and the second prefabricated layer 513a in the substrate may include performing the first doping on the substrate to form the first prefabricated layer 515a; performing the second doping on the substrate to form the second prefabricated layer 513a. For example, in performing the second doped on the substrate, the substrate may be lightly N-type doped to form the second prefabricated layer 513a.

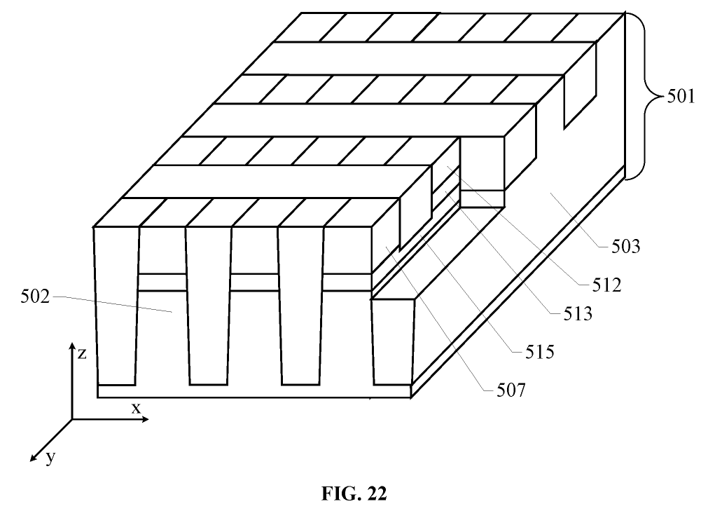

In some embodiments, forming the diode switching device may further include, as shown in FIG. 22, forming an interconnect activation layer 507 along the second direction y, where the interconnect activation layer 507 may be on the side of the memory units arranged along the second direction y.

In some embodiments, for forming the first doped layer 512 and the second doped layer 513, a part of the second prefabricated layers 513b arranged along the second direction y may be doped to form the first doped layer 512 and the second doped layer 513, and at least one second prefabricated layer 513b may remain on the side of the column of second doped layers 513 arranged along the second direction y; for forming the interconnect activation layer 507, the second prefabricated layers 513b on the side of the column of second doped layers 513 arranged along the second direction y may be doped to form the interconnect activation layers 507.

As shown in FIG. 23, in some embodiments, forming the diode switching device may further include forming the connection layer 514 on the first doped layer 512. For example, for forming the connection layer 514 on the first doped layer 512, the connection layers 514 may be formed on the first doped layer 512 and the interconnect activation layer 507, respectively.

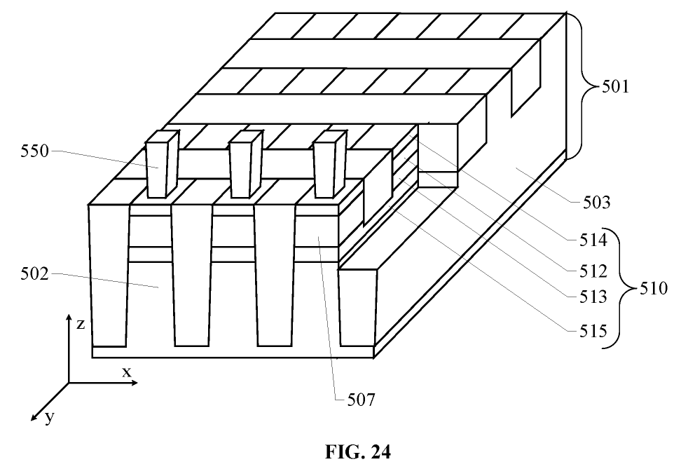

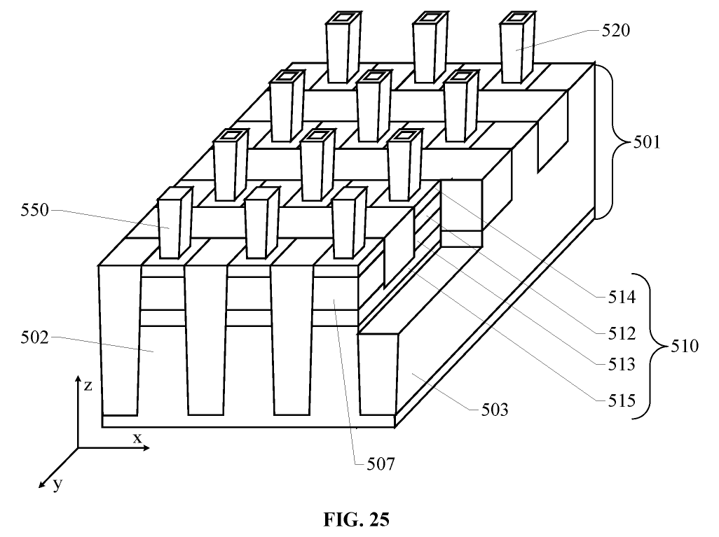

Referring to FIGS. 24-25, the first contact window 520 may be formed; the first contact window 520 may be described in the present disclosure; and an end of the first contact window 520 may be electrically connected to an end of the switching device 510.

In some embodiments of the present disclosure, for forming the first contact window 520, the third contact window 550 (as shown in FIG. 24) may be formed on the interconnect activation layer 507, and the first contact window 520 (as shown in FIG. 25) may be formed on the first doped layer 512.

In some embodiments, after forming the third contact window at the surface of the connection layer 514 on the interconnect activation layer 507, the first contact window 520 at the surface of the connection layer 514 on the first doped layer 512 may be formed.

In other embodiments of the present disclosure, the third contact window at the surface of the connection layer on the interconnect activation layer may be formed after forming the first contact window at the surface of the connection layer on the first doped layer; or the first contact window at the surface of the connection layer on the first doped layer and the third contact window at the surface of the connection layer on the interconnect activation layer may be formed simultaneously.

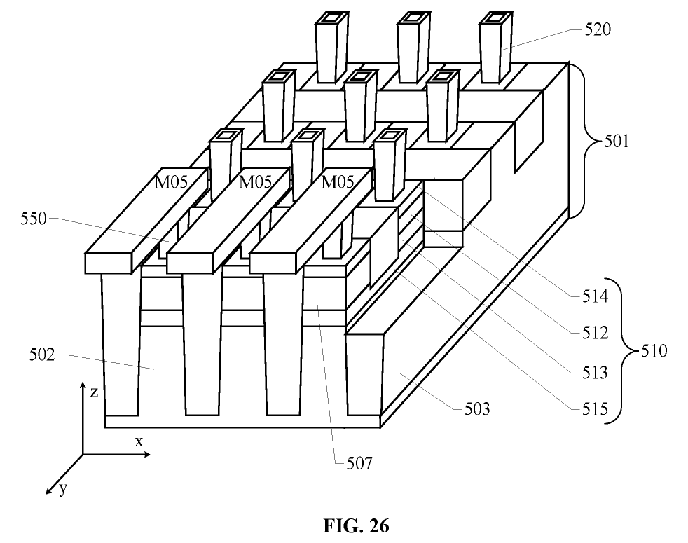

It should be noted that, in some embodiments of the present disclosure, as shown in FIG. 26, after forming the first contact window 520, the first metal M05 may be formed, and the first metal M05 may be electrically connected to the interconnect activation layer 507 through the third contact window 550.

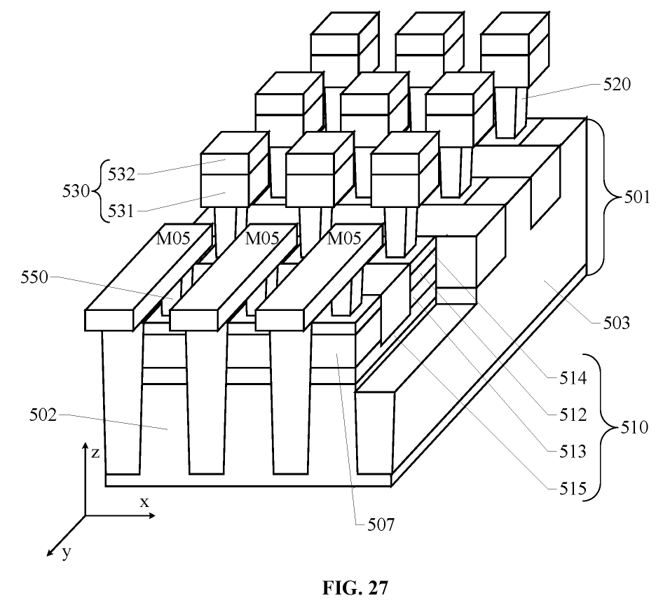

Referring to FIG. 27, a memory element 530 may be formed; and the memory element 530 may be on the side of the first contact window 520 away from the switching device 510 and electrically connected to another end of the first contact window 520.

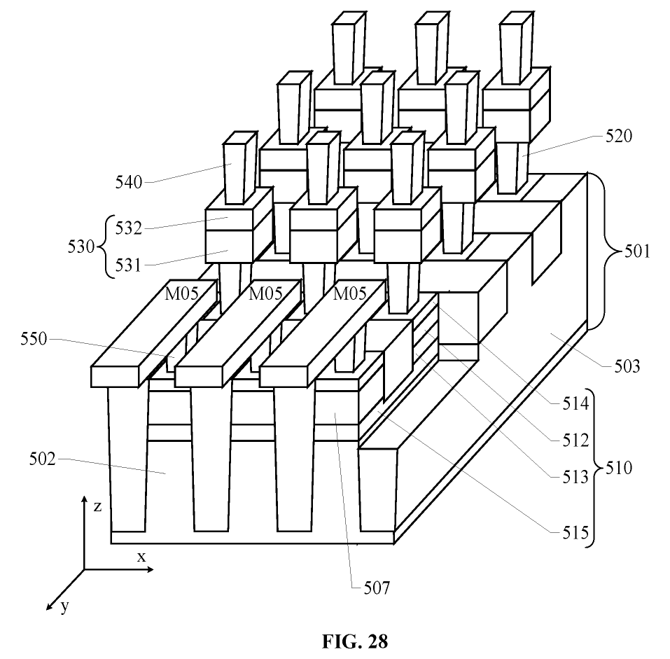

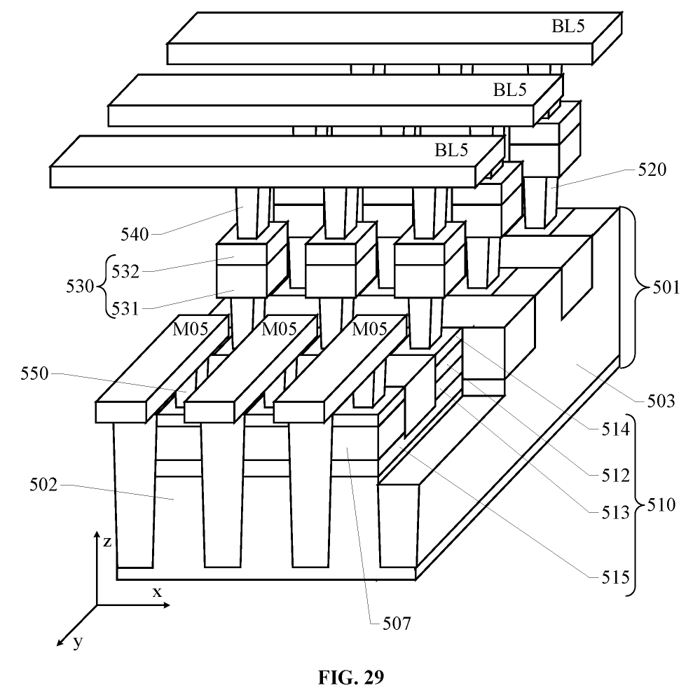

It should be noted that, in some embodiments of the present disclosure, after forming the memory element 530, as shown in FIG. 28, the second contact window 540 may be formed on the upper-layer electrode 532 of the memory element 530; and as shown in FIG. 29, the bit line BL5 may be formed on the second contact window 540.

As disclosed above, the filling metal only fills a portion of the hollow shell enclosed by the conductive blocking layer; on the side of the open structure, the filling metal is separated from the rear-layer part to-be-connected; and the contact area of the contact window and the rear-layer part to-be-connected is only the end surface of the conductive blocking layer. The contact area between the contact window and the rear-layer part to-be-connected may be relatively small, and the shape change of the contact window may be relatively small, which may reduce the contact area while simplifying the fabrication process, reduce the number of photomasks and process steps, lower process difficulty, and simultaneously reduce production costs.

Although the present disclosure has been disclosed above, the present disclosure may be not limited thereto. Any changes and modifications may be made by those skilled in the art without departing from the spirit and scope of the disclosure, and the scope of the disclosure should be determined by the scope defined by the appended claims.

What is claimed is:

1. A contact window, comprising:
a conductive blocking layer, wherein the conductive barrier-layer encloses a hollow shell; an end of the hollow shell is a sealed structure configured with a bottom surface; the bottom surface of the sealed structure is electrically connected to a first device to-be-connected; another end of the hollow shell is an open structure not configured a bottom surface; and an end surface of the open structure is electrically connected to a second device to-be-connected; and
a filling metal, wherein the filling metal fills a portion of the hollow shell enclosed by the conductive blocking layer.

2. The contact window according to claim 1, wherein:
the filling metal fills a portion of the hollow shell enclosed by the conductive barrier-layer and adjacent to the first device to-be-connected; and/or
the contact window further includes a first insulating material, filled between the filling metal and the second device to-be-connected.

3. The contact window according to claim 2, wherein:
a surface of the first insulating material facing toward the second device to-be-connected is in a contact with the second device to-be-connected; and/or
along a direction of a line connecting the filling metal and the second device to-be-connected, a thickness of the first insulating material is less than 1/2 of a distance between the filling metal and the second device to-be-connected; and/or
the first insulating material is made of at least one of silicon nitride and silicon oxide.

4. The contact window according to claim 1, wherein:
a thickness of the conductive barrier-layer is uniform; and/or
a thickness of the conductive barrier-layer is in a range of 1 nm to 20 nm; and/or
the conductive barrier-layer is made of at least one of titanium nitride, tantalum nitride, titanium, tantalum, and ruthenium.

5. The contact window according to claim 1, wherein:
a ratio of a thickness of the filling metal to a depth of the hollow shell is less than 2/3; and/or
the filling metal material is made of a material including tungsten, copper, and aluminum.

6. A memory unit, comprising:
a switching device;
a first contact window, wherein the first contact window includes:
a conductive blocking layer, wherein the conductive barrier-layer encloses a hollow shell; an end of the hollow shell is a sealed structure configured with a bottom surface; the bottom surface of the sealed structure is electrically connected to a first device to-be-connected; another end of the hollow shell is an open structure not configured a bottom surface; and an end surface of the open structure is electrically connected to a second device to-be-connected; and
a filling metal, wherein the filling metal fills a portion of the hollow shell enclosed by the conductive blocking layer; and one end of the first contact window is electrically connected to one end of the switching device; and
a memory element, wherein the memory element is on a side of the first contact window away from the switching device and electrically connected to another end of the first contact window.

7. The memory unit according to claim 6, wherein:
the memory element is a phase-change memory element; and the memory element includes a phase-change layer electrically connected to the first contact window, and an upper-layer electrode on a surface of the phase-change layer away from the first contact window; and/or
the switching device is a diode switching device; and the switching device includes a first doped layer electrically connected to the first contact window, and a second doped layer on a side of the first doped layer away from the first contact window, wherein a doped type of the second doped layer is different from a doped type of the first doped layer; and/or
the switching device is a transistor switching device; and the switching device includes a gate structure; and a first doped layer and a second doped layer, wherein along a plane perpendicular to a line connecting the switching device and the memory element, the first doped layer and the second doped layer are on two sides of the gate structure, and the first doped layer is electrically connected to the first contact window.

8. The memory unit according to claim 7, wherein:
the switching device further includes a connection layer; and the connection layer is between the first doped layer and the first contact window.

9. A memory device, comprising:
a memory array, wherein the memory array includes the memory units according to claim 6; the memory units are arranged in an array along a first direction and a second direction which are intersected with each other; both the first direction and the second direction are perpendicular to a third direction; and the third direction is a direction of a line connecting the sealed structure and the open structure.

10. The memory device according to claim 9, wherein:
the memory device further includes a bit line, wherein the bit line extends along the first direction and is electrically connected to a memory unit via a second contact window; and includes a first metal, wherein the first metal extends along the second direction and is electrically connected to another end of the switching device via a third contact window; and/or
the bit line is on a side of the memory element away from the first contact window; and/or
memory units arranged along the first direction are connected to a same bit line.

11. The memory device according to claim 9, wherein:
the switching device is a diode switching device; and
the switching device includes:
a first doped layer, electrically connected to the first contact window; and
a second doped layer, on a side of the first doped layer away from the first contact window, wherein a doped type of the second doped layer is different from a doped type of the first doped layer.

12. The memory device according to claim 11, wherein:
the switching device further includes an interconnect layer, wherein the interconnect layer is on a side of the second doped layer away from the first doped layer; and interconnect layers of switching devices of memory units arranged along the second direction extend to be connected with each other.

13. The memory device according to claim 12, further including:
an interconnect activation layer, wherein:
along the second direction, the interconnect activation layer is on a side of the memory units arranged along the second direction;
the interconnect layer extends to a position of the interconnect activation layer and is electrically connected to the interconnect activation layer; and
a first metal is on a side of the interconnect activation layer away from the interconnect layer; and an end of the first metal along the second direction is electrically connected to the interconnect activation layer through a third contact window.

14. The memory device according to claim 9, wherein:
the switching device is a transistor switching device; and
the switching device includes:
a gate structure; and
a first doped layer and a second doped layer, wherein along a plane perpendicular to a line connecting the switching device and the memory element, the first doped layer and the second doped layer are on two sides of the gate structure, and the first doped layer is electrically connected to the first contact window.

15. The memory device according to claim 14, wherein:
second doped regions of the memory units arranged along the second direction are connected to a same first metal; and/or
two memory units along the first direction are respectively a first memory unit and a second memory unit; a memory element of the first memory unit and a memory element of the second memory unit extend to be connected with each other; and a first metal electrically connected to the first memory unit and a first metal electrically connected to the second memory unit are respectively on two sides of a gate structure of a switching device of the first memory unit and a gate structure of a switching device of the second memory unit along the first direction.

16. A fabrication method of a memory device, comprising:
forming a switching device;
forming a first contact window, wherein the first contact window includes:
a conductive blocking layer, wherein the conductive barrier-layer encloses a hollow shell; an end of the hollow shell is a sealed structure configured with a bottom surface; the bottom surface of the sealed structure is electrically connected to a first device to-be-connected; another end of the hollow shell is an open structure not configured a bottom surface; and an end surface of the open structure is electrically connected to a second device to-be-connected; and
a filling metal, wherein the filling metal fills a portion of the hollow shell enclosed by the conductive blocking layer; and one end of the first contact window is electrically connected to one end of the switching device; and
forming a memory element, wherein the memory element is on a side of the first contact window away from the switching device and electrically connected to another end of the first contact window.

17. The method according to claim 16, further including:
forming a bit line, wherein the bit line extends along the first direction and is electrically connected to a memory unit via a second contact window; and
forming a first metal, wherein the first metal extends along the second direction and is electrically connected to another end of the switching device via a third contact window.

18. The method according to claim 16, wherein:
for forming the switching device, a diode switching device is formed;
for forming the switching device, an interconnect activation layer is formed, wherein along a second direction, the interconnect activation layer is on a side of memory units arranged along the second direction; and
after forming the first contact window and before forming the memory element, a first metal is formed, and the first metal is electrically connected to the interconnect activation layer through a third contact window.

19. The method according to claim 16, wherein:
for forming the switching device, a transistor switching device is formed; and for forming the first contact window, the first contact window above the first doped layer and the third contact window above the second doped layer are formed.

20. The method according to claim 19, wherein:
after forming the memory element, a first metal is formed; and after forming the first metal, a bit line is formed.
